(19) United States
(12) Patent Application Publication
(10) Pub. No.: US 2026/0112313 A1
(43) Pub. Date: Apr. 23, 2026

(54) ELECTRONIC DEVICE

(71) Applicant: Samsung Display Co., Ltd., Yongin-si (KR)

(72) Inventors: Wonjun LEE, Yongin-si (KR); Sungmin SON, Yongin-si (KR); Minji KIM, Yongin-si (KR); Geumju MOON, Yongin-si (KR)

(73) Assignee: Samsung Display Co., Ltd., Yongin-si (KR)

(21) Appl. No.: 19/265,717

(22) Filed: Jul. 10, 2025

(30) Foreign Application Priority Data
Oct. 18, 2024 (KR) 10-2024-0143347

(51) Int. Cl. G09G 3/3233; G09G 3/00; G09G 3/20; H10K 59/131

(52) U.S. Cl. CPC G09G 3/3233; G09G 3/035; H10K 59/131; G09G 3/2007; G09G 2300/0819; G09G 2300/0842; G09G 2300/0861; G09G 2310/06; G09G 2310/08; G09G 2330/023

(57) ABSTRACT

An electronic device includes a base layer, a pixel in a first region on the base layer, a plurality of scan lines including a first scan line electrically connected to the pixel, an emission control line electrically connected to the pixel, a scan driving circuit electrically connected to the plurality of scan lines, an emission driving circuit electrically connected to the emission control line, a plurality of driving voltage lines electrically connected to the pixel, and a plurality of signal lines including a first signal line electrically connected to the scan driving circuit, and a second signal line electrically connected to the emission driving circuit, wherein a load of a first circuit including the first scan line and the first signal line is greater than a load of a second circuit including the emission control line and the second signal line.

### CROSS-REFERENCE TO RELATED APPLICATIONS

This U.S. non-provisional patent application claims priority under 35 U.S.C. § 119 of Korean Patent Application No. 10-2024-0143347, filed on Oct. 18, 2024, the entire contents of which are hereby incorporated by reference.

### BACKGROUND

Multimedia electronic devices such as televisions, mobile phones, tablet computers, navigation system units, game consoles, and/or smart watches include a display panel and/or a driving circuit for displaying images. The driving circuit includes a scan driving circuit configured to provide scan signals to a plurality of scan lines, a data driving circuit configured to provide data voltages to data lines, and/or an emission driving circuit configured to provide an emission signal to an emission control line.

### SUMMARY

Example embodiments of inventive concepts provide an electronic device with reduced power consumption.

Some example embodiments of the inventive concepts provide an electronic device including a base layer including a first region and a second region adjacent to the first region, a pixel in the first region, a plurality of scan lines in the first region, and including a first scan line electrically connected to the pixel, an emission control line in the first region, and electrically connected to the pixel, a scan driving circuit in the second region, and electrically connected to the plurality of scan lines, an emission driving circuit in the second region, and electrically connected to the emission control line, a plurality of driving voltage lines in the second region, and electrically connected to the pixel, and a plurality of signal lines in the second region, the plurality of signal lines including a first signal line electrically connected to the scan driving circuit, and a second signal line electrically connected to the emission driving circuit, wherein a load of a first circuit including the first scan line and the first signal line is larger than a load of a second circuit including the emission control line and the second signal line.

In some example embodiments, the plurality of scan lines may further include a second scan line, a third scan line, and a fourth scan line, and the plurality of signal lines may further include a third signal line, a fourth signal line, and a fifth signal line, which are electrically connected to the scan driving circuit.

In some example embodiments, the scan driving circuit may be configured to output a first scan signal to the first scan line, the emission driving circuit may be configured to output an emission signal to the emission control line, wherein in a self-period, the scan driving circuit may be configured to maintain a level of the first scan signal, and the emission driving circuit may be configured to change a level of the emission signal.

In some example embodiments, the scan driving circuit may be configured to output a second scan signal to the second scan line, output a third scan signal to the third scan line, and output a fourth scan signal to the fourth scan line, wherein in the self-period, the scan driving circuit may be configured to maintain a level of the second scan signal and a level of the third scan signal, and change a level of the fourth scan signal.

In some example embodiments, the load of the second circuit may be smaller than each of a load of a third circuit including the second scan line and the third signal line and a load of a fourth circuit including the third scan line and the fourth signal line.

In some example embodiments, a load of a fifth circuit including the fourth scan line and the fifth signal line may be smaller than each of the load of the first circuit, the load of the third circuit, and the load of the fourth circuit.

In some example embodiments, a first width of the first scan line may be larger than a second width of the emission control line.

In some example embodiments, a first distance between the first scan line and a plurality of other scan lines adjacent to the first scan line may be smaller than a second distance between the emission control line and a plurality of other scan lines adjacent to the emission control line.

In some example embodiments, a capacitive load of the first scan line may be larger than a capacitive load of the emission control line.

In some example embodiments, the plurality of scan lines may further include a second scan line, a third scan line, and a fourth scan line, and the capacitive load of the emission control line may be smaller than each of a capacitive load of the second scan line, and a capacitive load of the third scan line.

In some example embodiments, a capacitive load of the fourth scan line may be smaller than each of the capacitive load of the first scan line, the capacitive load of the second scan line, and the capacitive load of the third scan line.

In some example embodiments, the plurality of driving voltage lines may include a first driving voltage line to which a first driving voltage is provided and a second driving voltage line to which a second driving voltage is provided, wherein the first driving voltage line may include a first overlapping portion overlapping the plurality of signal lines on a plane, and the second driving voltage line may include a second overlapping portion overlapping the plurality of signal lines on the plane.

In some example embodiments, the first overlapping portion may include a first opening.

In some example embodiments, the first opening may include a plurality of first openings.

In some example embodiments, the first overlapping portion may include a first opening and the second overlapping portion may include a second opening.

In some example embodiments, the first opening may include a plurality of first openings and the second opening may include a plurality of second openings.

In some example embodiments of the inventive concept, an electronic device includes a display panel including a display region and a non-display region adjacent to the display region, wherein the display panel includes a pixel in the display region, and including a pixel circuit and an emission element, a first scan line electrically connected to the pixel circuit, and an emission control line electrically connected to the pixel circuit, wherein a capacitive load of the first scan line is larger than a capacitive load of the emission control line.

In some example embodiments, the electronic device may further include processing circuitry configured to operate the pixel circuit based on a data write period and a self-period, change a level of a first scan signal provided to the first scan line in the data write period, maintain the level of the first scan signal in the self-period, and change a level of an emission signal provided to the emission control line in the data write period and the self-period.

In some example embodiments, the display panel may further include a second scan line, a third scan line, and a fourth scan line, wherein the capacitive load of the emission control line may be smaller than each of a capacitive load of the second scan line, and a capacitive load of the third scan line, a capacitive load of the fourth scan line may be smaller than each of the capacitive load of the first scan line, the capacitive load of the second scan line, and the capacitive load of the third scan line, and wherein the processing circuitry may be configured to maintain a level of each of signals provided to the second scan line and the third scan line in the self-period, and change a level of a signal provided to the fourth scan line in the self-period.

In some example embodiments, the display panel may further include a plurality of signal lines in the non-display region and a driving voltage line in the non-display region, the driving voltage line configured to transfer a driving voltage to the pixel, and the driving voltage line may include at least one opening overlapping the plurality of signal lines on a plane.

### BRIEF DESCRIPTION OF THE FIGURES

The accompanying drawings are included to provide a further understanding of the inventive concepts, and are incorporated in and constitute a part of this specification. The drawings illustrate some example embodiments of the inventive concepts and, together with the description, serve to explain principles of the inventive concepts. In the drawings:

FIG. 1A is a perspective view of an electronic device according to some example embodiments of the inventive concepts;

FIG. 1B is a rear-surface perspective view of an electronic device according to some example embodiments of the inventive concepts;

FIG. 2A is a perspective view of an electronic device according to some example embodiments of the inventive concepts;

FIG. 2B is a plan view of an electronic device according to some example embodiments of the inventive concepts;

FIG. 3 is a block diagram of an electronic device according to some example embodiments of the inventive concepts;

FIG. 4A is a circuit diagram of a pixel according to some example embodiments of the inventive concepts;

FIG. 4B is a circuit diagram of a pixel according to some example embodiments of the inventive concepts;

FIG. 5 is a cross-sectional view of a display panel according to some example embodiments of the inventive concepts;

FIG. 6 is a schematic block diagram of a display panel according to some example embodiments of the inventive concepts;

FIG. 7 is a timing diagram showing signals according to some example embodiments of the inventive concepts;

FIG. 8 is a plan view of a portion of a display panel according to some example embodiments of the inventive concepts;

FIG. 9A is an enlarged plan view of region AA′ of FIG. 8 according to some example embodiments of the inventive concepts;

FIG. 9B is an enlarged plan view of region AA′ of FIG. 8 according to some example embodiments of the inventive concepts;

FIG. 10A is an enlarged plan view of region AA′ of FIG. 8 according to some example embodiments of the inventive concepts;

FIG. 10B is an enlarged plan view of region AA′ of FIG. 8 according to some example embodiments of the inventive concepts;

FIG. 10C is an enlarged plan view of region AA′ of FIG. 8 according to some example embodiments of the inventive concepts;

FIG. 10D is an enlarged plan view of region AA′ of FIG. 8 according to some example embodiments of the inventive concepts;

FIG. 10E is an enlarged plan view of region AA′ of FIG. 8 according to some example embodiments of the inventive concepts;

FIG. 10F is an enlarged plan view of region AA′ of FIG. 8 according to some example embodiments of the inventive concepts;

FIG. 10G is an enlarged plan view of region AA′ of FIG. 8 according to some example embodiments of the inventive concepts;

FIG. 11 is a table showing the power consumption of a display panel according to some example embodiments of the inventive concepts;

FIG. 12A is a layout of a plurality of scan lines and an emission control line according to some example embodiments of the inventive concepts;

FIG. 12B is a layout of a plurality of scan lines and an emission control line according to some example embodiments of the inventive concepts;

FIG. 13 is a table showing numerical values of capacitive loads of a plurality of scan lines and an emission control line according to some example embodiments of the inventive concepts; and

FIG. 14 is a table showing the power consumption of a display panel according to some example embodiments of the inventive concepts.

### DETAILED DESCRIPTION

In this specification, it will be understood that when an element (or a region, a layer, a portion, or the like) is referred to as being “on”, “connected to” or “coupled to” another element, it may be directly disposed on, connected to, or coupled to the other element, or other elements may be disposed therebetween.

Like reference numerals or symbols refer to like elements throughout. In the drawings, the thickness, ratio, and size of the elements are exaggerated for effectively describing the technical contents. As used herein, the term “and/or” includes any and all combinations of one or more of the associated listed elements.

It will be understood that, although the terms “first”, “second”, etc. may be used herein to describe various elements, the elements are not to be limited by these terms. These terms are only used to distinguish one element, component, region, layer and/or section from another element, component, region, layer and/or section. For instance, a first element could be termed a second element without departing from the scope of the inventive concept. Similarly, a second element could be termed a first element. In this specification, singular expressions are intended to include plural forms as well, unless the context clearly indicates otherwise.

In addition, the terms “below”, “under”, “on the lower side”, “above”, “over”, “on the upper side”, or the like may be used to describe the relationships between the elements illustrated in the drawings. These terms are relative concepts and are described on the basis of the directions indicated in the drawings.

It will be further understood that the terms “comprises”, “includes”, “has“, and/or ”comprising”, “including”, “having”, when used in this specification, specify the presence of stated features, numbers, steps, operations, elements, components or combinations thereof, but do not preclude the possibility of the presence and/or addition of one or more other features, numbers, steps, operations, elements, components, and/or combinations thereof.

The terms “part” and/or “unit” refer to a software component and/or a hardware component that performs a particular function. The hardware component may include, for example, a field-programmable gate array (FPGA) or an application-specific integrated circuit (ASIC). The software component may refer to an executable code and/or data used by an executable code in an addressable storage medium. Therefore, software components may be, for example, object-oriented software components, class components, and/or work components, and/or may include processes, functions, attributes, procedures, subroutines, program code segments, drivers, firmware, micro codes, circuits, data, databases, data structures, tables, arrangements, and/or variables.

When an element is referred to as being “connected to” or “electrically connected to” another element, the element may be directly connected to the other element, or one or more other intervening elements may be present. For example, an element described as being “connected to” another element may be “electrically connected to” the other element. In contrast, when an element is referred to as being “directly connected to” another element there are no intervening elements present.

Unless otherwise defined, all terms (including technical and scientific terms) used herein have the same meaning as commonly understood by one of ordinary skill in the art to which the inventive concepts belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, some example embodiments of the inventive concepts will be described with reference to the accompanying drawings.

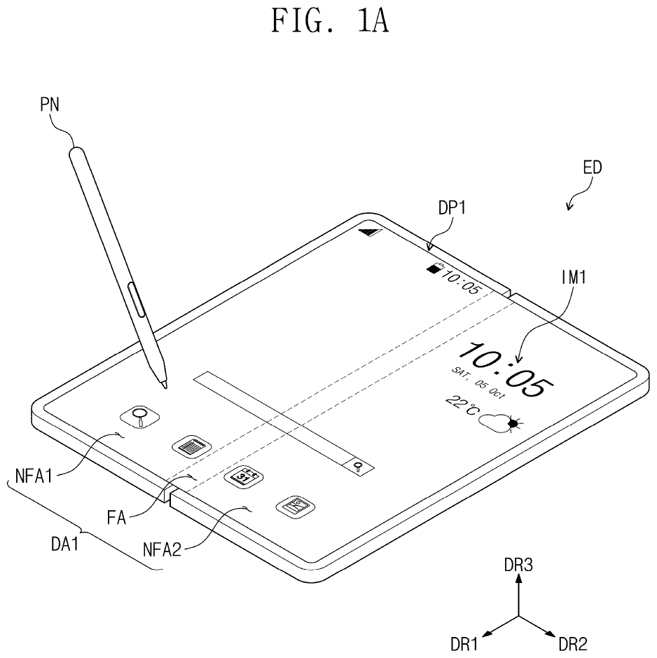

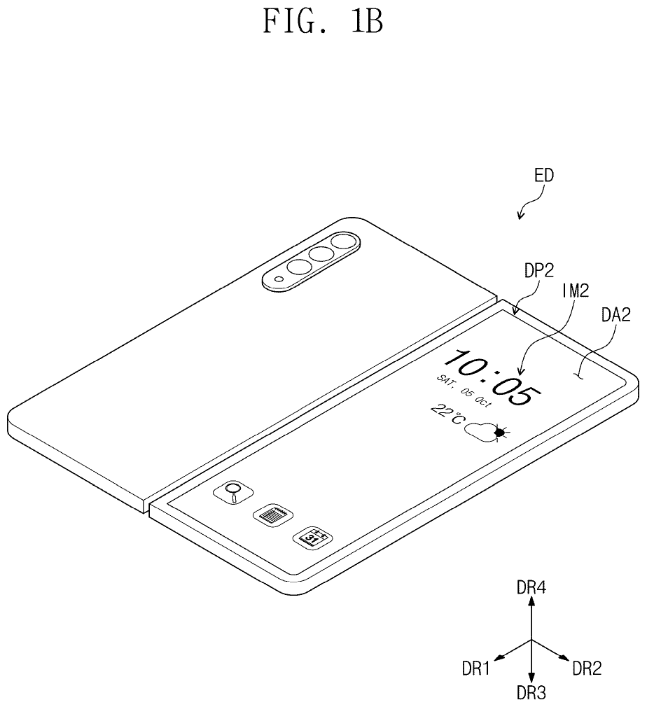

FIG. 1A is a perspective view of an electronic device ED according to some example embodiments of the inventive concepts. FIG. 1B is a rear-surface perspective view of the electronic device ED according to some example embodiments of the inventive concepts.

Referring to FIG. 1A and FIG. 1B, an electronic device ED may be a device activated by an electrical signal. For example, the electronic device ED may display images, and may sense inputs applied from outside of the electronic device ED. An external input may be a user input. The user input may include various forms of external inputs such as a part of a user's body, a pen PN, light, heat, and/or pressure.

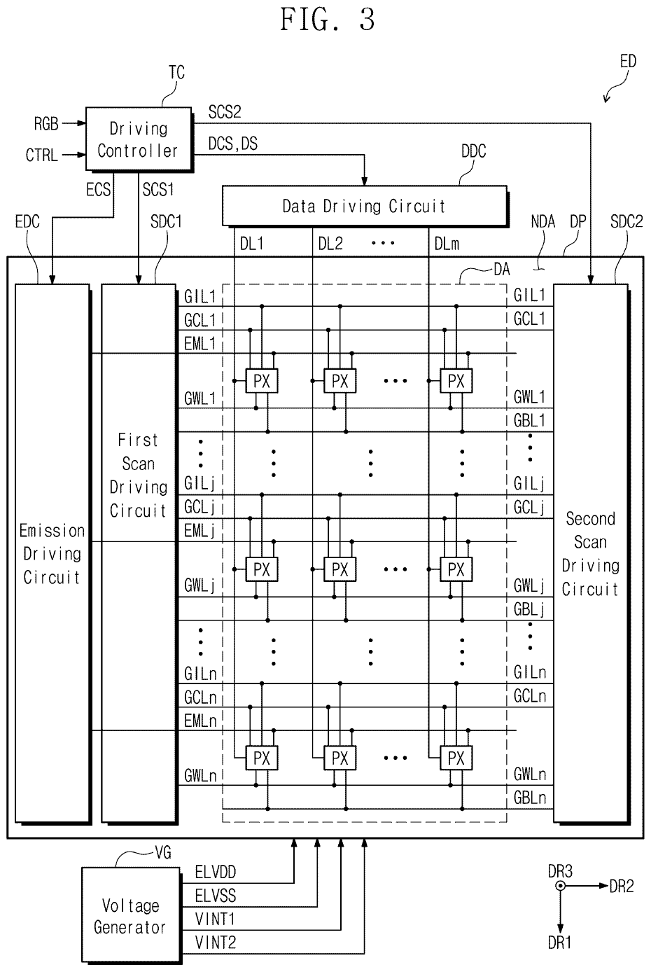

The electronic device ED may include a first display panel DP1 and/or a second display panel DP2. The first display panel DP1 and the second display panel DP2 may be separate panels separated from each other. The first display panel DP1 may be referred to as a main display panel, and the second display panel DP2 may be referred to as an auxiliary display panel or an external display panel. The first display panel DP1 and the second display panel DP2 may be referred to as a display panel DP (see FIG. 3).

The first display panel DP1 may include a first display region DA1, and the second display panel DP2 may include a second display region DA2. The area of the second display panel DP2 may be smaller than the area of the first display panel DP1. Corresponding to the size of the first display panel DP1 and the second display panel DP2, the area of the first display region DA1 may be larger than the area of the second display region DA2.

The first display panel DP1 and the second display panel DP2 may each include a non-display region NDA (see FIG. 3). The first display region DA1 and the second display region DA2 may be referred to as a display region DA (see FIG. 3).

When the electronic device ED is in an unfolded state, the first display region DA1 may have a plane substantially parallel to a first direction DR1 and a second direction DR2. A thickness direction of the electronic device ED may be parallel to a third direction DR3 crossing the first direction DR1 and the second direction DR2. Therefore, a front surface (or an upper surface) and a rear surface (or a lower surface) of members constituting the electronic device ED may be defined based on the third direction DR3.

The first display panel DP1 and/or the first display region DA1 may include a folding region FA which is folded and unfolded, and a plurality of non-folding regions NFA1 and/or NFA2 which are spaced apart from each other with the folding region FA interposed therebetween. The second display panel DP2 may overlap any one of the plurality of non-folding regions NFA1 to NFA2. For example, the second display panel DP2 may overlap the first non-folding region NFA1.

A display direction of a first image IM1 displayed in a portion of the first display panel DP1, e.g., the first non-folding region NFA1 and a display direction of a second image IM2 displayed in the second display panel DP2 may be opposite directions. For example, the first image IM1 may be displayed in the third direction DR3, and the second image IM2 may be displayed in a fourth direction DR4, which is a direction opposite to the third direction DR3.

In some example embodiments of the inventive concepts, the folding region FA may be bent with respect to a folding axis extending in a direction parallel to a long side of the electronic device ED, e.g., a direction parallel to the first direction DR1. When the electronic device ED is in a folded stated, the folding region FA has a predetermined, or alternately given, curvature and a predetermined, or alternately given, radius of curvature. The first non-folding region NFA1 and the second non-folding region NFA2 may face each other, and the electronic device ED may be inner-folded such that the first display region DA1 is not exposed to the outside.

In some example embodiments of the inventive concepts, the electronic device ED may be outer-folded such that the first display region DA1 is exposed to the outside. In some example embodiments of the inventive concepts, the electronic device ED may be inner-folded or outer-folded when in an unfolded state, but example embodiments are not limited to this example.

Although FIG. 1A illustrates an example in which one folding region FA is defined (provided or included) in the electronic device ED, some example embodiments of the inventive concepts are not limited to this example. For example, in the electronic device ED, a plurality of folding axes and a plurality of folding regions corresponding thereto may be defined, and the electronic device ED may be inner-folded and/or outer-folded when in a folded state in each of the plurality of folding regions.

In some example embodiments of the inventive concepts, even without including a digitizer, at least one of the first display panel DP1 and/or the second display panel DP2 may sense an input by a pen PN. Therefore, since a digitizer for sensing the pen PN is omitted, there may not be an increase in the thickness, an increase in the weight, and/or degradation in the flexibility of the electronic device ED due to the addition of the digitizer. Therefore, not only the first display panel DP1, but also the second display panel DP2 may be designed to sense the pen PN.

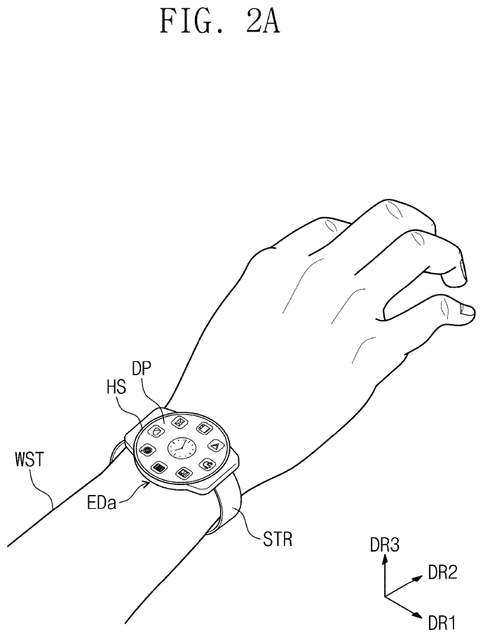

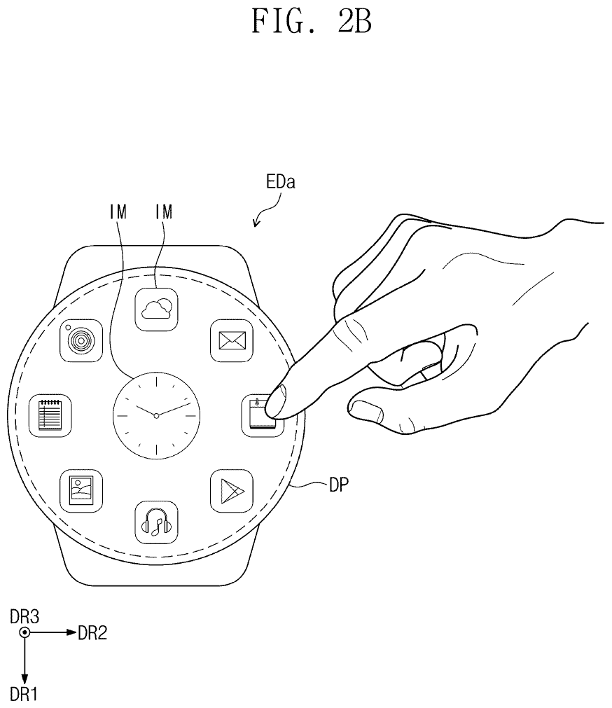

FIG. 2A is a perspective view of an electronic device EDa according to some example embodiments of the inventive concepts. FIG. 2B is a plan view of the electronic device EDa according to some example embodiments of the inventive concepts.

Referring to FIG. 2A and FIG. 2B, the electronic device EDa may include a display panel DP, a housing HS in which the display panel DP is embedded, and/or a strap STR connected to the housing HS.

According to some example embodiments of the inventive concepts, a user may use the electronic device EDa while wearing the electronic device ED on the user's wrist WST. The user may arrange the strap STR, which is connected to the housing HS in which the display panel DP is embedded, to surround the user's wrist WST. In this case, the user may arrange a display surface of the display panel DP to face the user.

Although FIG. 2A illustrates an example in which the electronic device EDa is a smart watch including the housing HS and the strap STR, some example embodiments of the inventive concepts are not limited to this example. For example, the electronic device EDa may be an electronic device EDa employed in a television, a monitor, an external billboard, a tablet, a car navigation unit, a personal computer, a notebook computer, a personal digital terminal, a game console, a smart phone, a camera, and/or a wearable device. The wearable device may include a virtual reality device, an augmented reality device, a smart watch, and/or the like. The virtual reality device and/or the augmented reality device may be devices in the form of glasses that the user may wear. These devices are presented only as examples, and the electronic device EDa may be employed in other devices without departing from the inventive concepts.

The display panel DP may display the image IM. The display panel DP may provide various images IM to the user. The image IM may show time and various applications. For example, the display panel DP may display and provide, to the user, an hour hand and a minute hand showing the time. In addition, the display panel DP may display and provide, to the user, the various applications.

The electronic device EDa may be a touch-type device. For example, when the user touches applications displayed on the display panel DP, the touched applications may be executed. For example, when the user touches an application for the weather among applications displayed on the display panel DP, information on the weather may be provided to the user.

An upper surface of the display panel DP may be defined as a display surface, and may have a plane defined by the first direction DR1 and the second direction DR2. The first direction DR1 and the second direction DR2 may be defined as directions perpendicularly crossing each other. Through the display surface, the image IM generated in the electronic device EDa may be provided to the user.

The display surface may include a display region DA and/or a non-display region NDA around the display region DA. The display region DA may display an image, and the non-display region NDA may not display an image. The non-display region NDA may surround the display region DA.

When viewed on a plane, the electronic device EDa may have a circular shape, but example embodiments are not limited to this example, and the electronic device ED may have various shapes such as a rectangular shape, a polygonal shape, or an oval shape.

FIG. 3 is a block diagram of the electronic device ED according to some example embodiments of the inventive concepts.

Referring to FIG. 3, the electronic device ED may include a display panel DP, a driving controller TC, a data driving circuit DDC, a first scan driving circuit SDC1, a second scan driving circuit SDC2, an emission driving circuit EDC, and/or a voltage generator VG.

The driving controller TC may receive an input signal including an input image signal RGB and/or a control signal CTRL. The driving controller TC may generate an output image signal DS obtained by converting a data format of the input image signal RGB to meet interface specifications with the data driving circuit DDC. The driving controller TC may output a first scan control signal SCS1, a second scan control signal SCS2, an emission control signal ECS, and/or a data control signal DCS to control an image to be displayed on the display panel DP.

The data driving circuit DDC may receive the data control signal DCS and/or the output image signal DS from the driving controller TC. The data driving circuit DDC may convert the output image signal DS into data signals, and may output the data signals to a plurality of data lines DL1 to DLm to be described later. The data signals may be analog voltages corresponding to gray scale values of the output image signal DS.

The display panel DP may include a display region DA and/or a non-display region NDA adjacent to the display region DA. The display region DA and the non-display region NDA may be referred to a first display region DA and a second display region NDA, respectively.

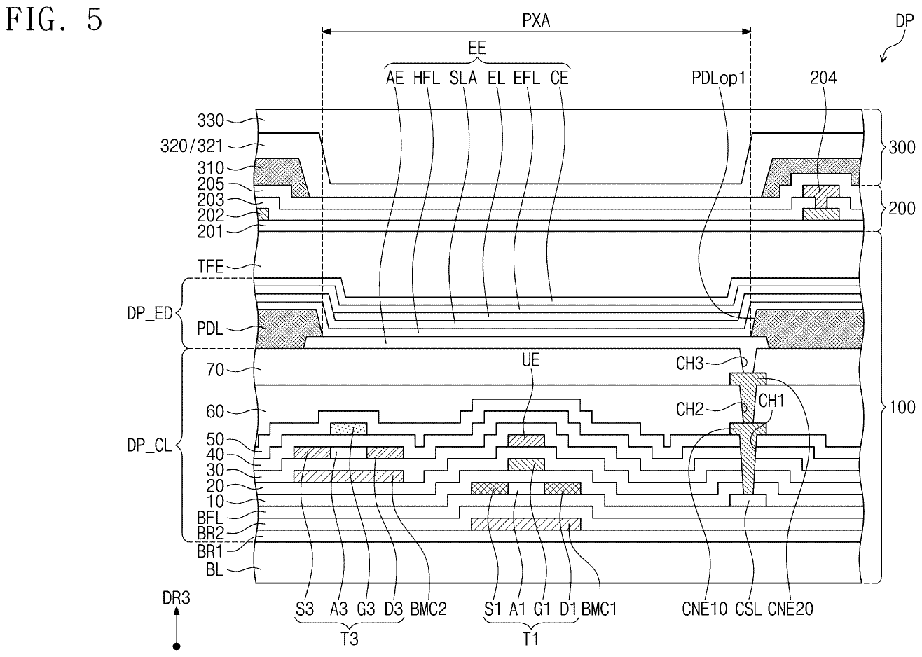

The display panel DP may include the first scan driving circuit SDC1, the second scan driving circuit SDC2, and/or the emission driving circuit EDC. The first scan driving circuit SDC1, the second scan driving circuit SDC2, and/or the emission driving circuit EDC may be arranged in the non-display region NDA, e.g., the second region NDA of the base layer BL (see FIG. 5).

In some example embodiments, the first scan driving circuit SDC1 and/or the emission driving circuit EDC may be arranged on a first side of the display panel DP, and the second scan driving circuit SDC2 may be arranged on a second side of the display panel DP.

The display panel DP may include a plurality of data lines DL1 to DLm, a plurality of scan lines GWL1 to GWLn, GIL1 to GILn, GCL1 to GCLn, and/or GBL1 to GBLn, a plurality of emission control lines EML1 to EMLn, and/or a plurality of pixels PX. The data lines DL1 to DLm, the scan lines GWL1 to GWLn, GIL1 to GILn, GCL1 to GCLn, and/or GBL1 to GBLn, the emission control lines EML1 to EMLn, and/or the pixels PX may be arranged in the display region DA. For example, the data lines DL1 to DLm, the scan lines GWL1 to GWLn, GIL1 to GILn, GCL1 to GCLn, and GBL1 to GBLn, the emission control lines EML1 to EMLn, and the pixels PX may be arranged in the first region DA of the base layer BL (see FIG. 5).

The data lines DL1 to DLm may extend from the data driving circuit DDC in the first direction DR1, and may be arranged in the second direction DR2 while being spaced apart from each other.

The scan lines GWL1 to GWLn, GIL1 to GILn, GCL1 to GCLn, and/or GBL1 to GBLn may include first scan lines GWL1 to GWLn, second scan lines GIL1 to GILn, third scan lines GCL1 to GCLn, and/or fourth scan lines GBL1 to GBLn. The first scan lines GWL1 to GWLn, the second scan lines GIL1 to GILn, the third scan lines GCL1 to GCLn, and/or the fourth scan lines GBL1 to GBLn may be referred to as write scan lines GWL1 to GWLn, initialization scan lines GIL1 to GILn, compensation scan lines GCL1 to GCLn, and/or black scan lines GBL1 to GBLn.

The first scan lines GWL1 to GWLn, the second scan lines GIL1 to GILn, and/or the third scan lines GCL1 to GCLn may be electrically connected to the first scan driving circuit SDC1. The emission control lines EML1 to EMLn may be electrically connected to the emission driving circuit EDC. The first scan lines GWL1 to GWLn, the second scan lines GIL1 to GILn, the third scan lines GCL1 to GCLn, and/or the fourth scan lines GBL1 to GBLn may be electrically connected to the second scan driving circuit SDC2. Therefore, the first scan lines GWL1 to GWLn, the second scan lines GIL1 to GILn, and/or the third scan lines GCL1 to GCLn may be electrically connected to the first scan driving circuit SDC1 and the second scan driving circuit SDC2.

The first scan driving circuit SDC1 may receive the first scan control signal SCS1 from the driving controller TC. In response to the first scan control signal SCS1, the first scan driving circuit SDC1 may output first scan signals GW1 to GWn to the first scan lines GWL1 to GWLn, may output second scan signals GI1 to GIn to the second scan lines GIL1 to GILn, and/or may output third scan signals GC1 to GCn to the third scan lines GCL1 to GCLn.

The second scan driving circuit SDC2 may receive the second scan control signal SCS2 from the driving controller TC. In response to the second scan control signal SCS2, the second scan driving circuit SDC2 may output the first scan signals GW1 to GWn to the first scan lines GWL1 to GWLn, may output the second scan signals GI1 to GIn to the second scan lines GIL1 to GILn, may output the third scan signals GC1 to GCn to the third scan lines GCL1 to GCLn, and/or may output fourth scan signals GB1 to GBn to the fourth scan lines GBL1 to GBLn.

The first scan driving circuit SDC1 and the second scan driving circuit SDC2 may be referred to as a scan driving circuit.

The emission driving circuit EDC may receive the emission control signal ECS from the driving controller TC. In response to the emission control signal ECS, the emission driving circuit EDC may output emission signals EM1 to EMn to the emission control lines EML1 to EMLn.

In the example illustrated in FIG. 3, the first scan driving circuit SDC1 and the second scan driving circuit SDC2 are arranged facing the non-display region NDA with the display region DA interposed therebetween, but some example embodiments of the inventive concepts are not limited to this example. In some example embodiments, at least a portion of each of the first scan driving circuit SDC1 and/or the second scan driving circuit SDC2 may be arranged in the display region DA, and the display panel DP may include only one of the first scan driving circuit SDC1 and/or the second scan driving circuit SDC2.

The pixels PX may each, or one or more, be electrically connected to the first scan lines GWL1 to GWLn, the second scan lines GIL1 to GILn, the third scan lines GCL1 to GCLn, the fourth scan lines GBL1 to GBLn, the emission control lines EML1 to EMLn, and/or the data lines DL1 to DLm. Each, or one or more, of the pixels PX may be electrically connected to four scan lines and/or one emission control line. For example, as illustrated in FIG. 3, pixels in a first row may be electrically connected to first scan lines GIL1, GCL1, GWL1, and/or GBL1 and/or a first emission control line EML1. In addition, pixels in a j-th row may be electronically connected to j-th scan lines GILj, GCLj, GWLj, and/or GBLj and/or a j-th emission control line EMLj.

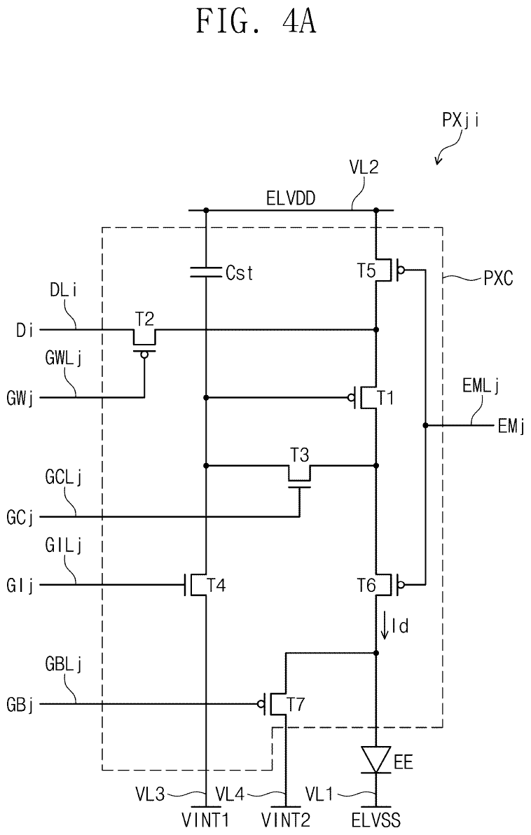

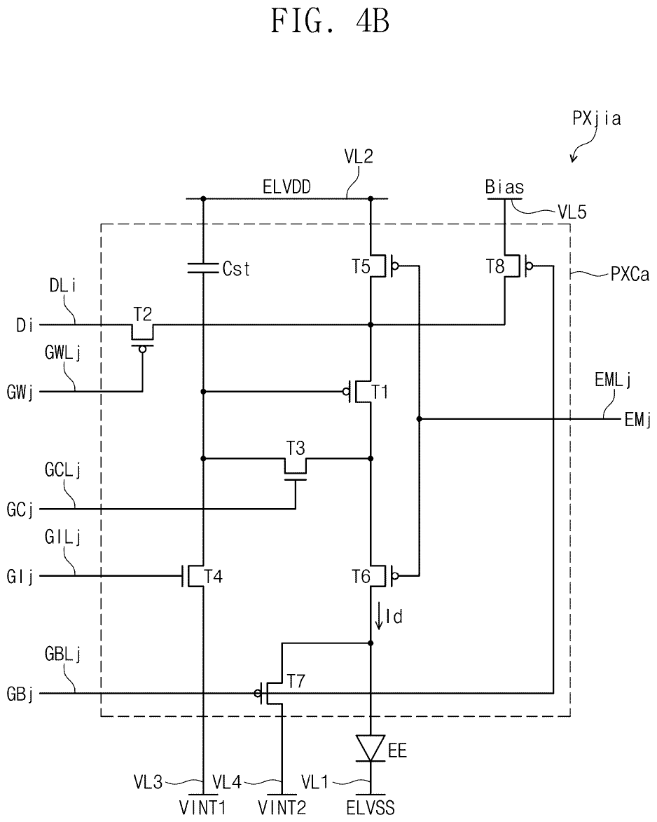

Each, or one or more, of the pixels PX may include an emission element EE (see FIG. 4A) and/or a pixel circuit PXC (see FIG. 4A) which controls emission of the emission element EE. The pixel circuit PXC may include one or more transistors and/or one or more capacitors. The first scan driving circuit SDC1, the second scan driving circuit SDC2, and/or the emission driving circuit EDC may include transistors formed through the same process as that of the pixel circuit PXC.

The voltage generator VG may generate voltages necessary, or sufficient, for an operation of the display panel DP. The voltage generator VG may generate a second driving voltage ELVDD, a first driving voltage ELVSS, a first initialization voltage VINT1, and/or a second initialization voltage VINT2.

Each, or one or more, of the pixels PX may receive the first driving voltage ELVSS, the second driving voltage ELVDD, the first initialization voltage VINT1, and/or the second initialization voltage VINT2 from the voltage generator VG.

FIG. 4A is a circuit diagram of a pixel PXji according to some example embodiments of the inventive concepts.

FIG. 4A illustrates an example of an equivalent circuit diagram of the pixel PXji electrically connected to an i-th data line DLi, a j-th first scan line GWLj, a j-th second scan line GILj, a j-th third scan line GCLj, a j-th fourth scan line GBLj, and/or a j-th emission control line EMLj in FIG. 3.

Each, or one or more, of the plurality of pixels PX illustrated in FIG. 3 may have the same circuit configuration as shown in the equivalent circuit diagram of the pixel PXji illustrated in FIG. 4A. In some example embodiments, the pixel circuit PXC of the pixel PXji may include first to seventh transistors T1, T2, T3, T4, T5, T6, and T7, a capacitor Cst, and/or at least one emission element EE. In some example embodiments, the emission element EE may be a light emitting diode.

Among the first to seventh transistors T1, T2, T3, T4, T5, T6, and T7, the third and/or fourth transistors T3 and/or T4 may be N-type transistors including an oxide semiconductor as a semiconductor layer, and each, or one or more, of the first, second, fifth, sixth, and/or seventh transistors T1, T2, T5, T6, and T7 may be a P-type transistor including a low-temperature polycrystalline silicon (LTPS) as a semiconductor layer. However, some example embodiments of the inventive concepts are not limited to this example, and all, or one or more, of the first to seventh transistors T1, T2, T3, T4, T5, T6, and/or T7 may be P-type transistors or N-type transistors. In some example embodiments, at least one of the first to seventh transistors T1, T2, T3, T4, T5, T6, and/or T7 may be an N-type transistor, and the others may be P-type transistors.

The first scan line GWLj may transfer a first scan signal GWj, the second scan line GILj may transfer a second scan signal GIj, the third scan line GCLj may transfer a third scan signal GCj, and/or the fourth scan line GBLj may transfer a fourth scan signal GBj. The emission control line EMLj may transfer an emission signal EMj.

The data line DLi may transfer a data signal Di. The data signal Di may have a voltage level corresponding to the input image signal RGB (see FIG. 3) input to the electronic device ED (see FIG. 3).

First to fifth driving voltage lines VL1, VL2, VL3, VL4, and/or VL5 may each, or one or more, be electrically connected to the pixel PXji. The first to fifth driving voltage lines VL1, VL2, VL3, VL4, and/or VL5 may each, or one or more, transfer the first driving voltage ELVSS, the second driving voltage ELVDD, the first initialization voltage VINT1, and/or the second initialization voltage VINT2. The first to fifth driving voltage lines VL1, VL2, VL3, VL4, and/or VL5 may each be referred to as a driving voltage line.

The first transistor T1 may include a first electrode electrically connected to the second driving voltage line VL2 via the fifth transistor T5, a second electrode electrically connected to an anode of the emission element EE via the sixth transistor T6, and/or a gate electrode electrically connected to one end of the capacitor Cst. The first transistor T1 may receive the data signal Di transferred by the data line DLi in accordance with a switching operation of the second transistor T2 and supply a driving current Id to the emission element EE.

The second transistor T2 may include a first electrode electrically connected to the data line DLi, a second electrode electrically connected to the first electrode of the first transistor T1, and/or a gate electrode electrically connected to the first scan line GWLj. The second transistor T2 may be turned on in response to the first scan signal GWj received through the first scan line GWLj and transfer the data signal DI transferred from the data line DLi to the first electrode of the first transistor T1.

The third transistor T3 may include a first electrode electrically connected to the gate electrode of the first transistor T1, a second electrode electrically connected to the second electrode of the first transistor T1, and/or a gate electrode electrically connected to the third scan line GCLj. The third transistor T3 may be turned on in response to the third scan signal GCj received through the third scan line GCLj and connect the gate electrode and the second electrode of the first transistor T1 to diode connect the first transistor T1.

The fourth transistor T4 may include a first electrode electrically connected to the gate electrode of the first transistor T1, a second electrode electrically connected to the third driving voltage line VL3 to which the first initialization voltage VINT1 is transferred, and/or a gate electrode electrically connected to the second scan line GILj. The fourth transistor T4 may be turned on in response to the second scan signal GIj received through the second scan line GILj and transfer the first initialization voltage VINT1 to the gate electrode of the first transistor T1 to perform an initialization operation which initializes the voltage of the gate electrode of the first transistor T1.

The fifth transistor T5 may include a first electrode electrically connected to the second driving voltage line VL2, a second electrode electrically connected to the first electrode of the first transistor T1, and/or a gate electrode electrically connected to the emission control line EMLj.

The sixth transistor T6 may include a first electrode electrically connected to the second electrode of the first transistor T1, a second electrode electrically connected the anode of the emission element EE, and a gate electrode electrically connected to the emission control line EMLj.

The fifth transistor T5 and the sixth transistor T6 may be simultaneously turned on in response to the emission signal EMj received through the emission control line EMLj, through which the second driving voltage ELVDD may be compensated through the diode-connected first transistor T1 and transferred to the emission element EE.

The seventh transistor T7 may include a first electrode electrically connected to the anode of the emission element EE, a second electrode electrically connected to the fourth driving voltage line VL4, and/or a gate electrode electrically connected to the fourth scan line GBLj. The seventh transistor T7 may be turned on in response to the fourth scan signal GBj received through the fourth scan line GBLj and bypass a current of the anode of the emission element EE to the fourth driving voltage line VL4.

One end of the capacitor Cst may be electrically connected to the gate electrode of the first transistor T1, and the other end thereof may be electrically connected to the second driving voltage line VL2.

The anode of the emission element EE may be electrically connected to the second electrode of the sixth transistor T6, and/or a cathode thereof may be electrically connected to the first driving voltage line VL1 which transfers the first driving voltage ELVSS.

The circuit configuration of the pixel PXji is not be limited to FIG. 4A, and the number of transistors, the number of capacitors, and/or the connection relationship therebetween included in the pixel circuit PXC inside the pixel PXji may vary. FIG. 4B is a circuit diagram of a pixel PXjia according to some example embodiments of the inventive concepts.

In FIG. 4B, the same components as those illustrated in FIG. 4A are denoted by the same reference numerals, and the descriptions thereof will be omitted.

Referring to FIG. 4B, the pixel PXjia may include a pixel circuit PXCa and an emission element EE.

In some example embodiments of the inventive concepts, the pixel circuit PXCa may further include an eighth transistor T8. The eighth transistor T8 may include a first electrode electrically connected to a bias voltage line VL5, a second electrode electrically connected to the first electrode of the first transistor T1, and/or a gate electrode electrically connected to the fourth scan line GBLj. The eighth transistor may be turned on in response to the fourth scan signal GBj received through the fourth scan line GBLj, through which a bias voltage may be compensated through the diode-connected first transistor T1 and transferred to the emission element EE.

The circuit configuration of the pixel PXjia is not be limited to FIG. 4B, and the number of transistors, the number of capacitors, and/or the connection relationship therebetween included in the pixel circuit PXCa inside the pixel PXjia may vary.

FIG. 5 is a cross-sectional view of the display panel DP according to some example embodiments of the inventive concepts.

Referring to FIG. 5, the display panel DP may include a display layer 100, a sensor layer 200, and/or a reflection prevention layer 300.

The display layer 100 may include a base layer BL, a circuit layer DP_CL arranged on the base layer BL, an element layer DP_ED, and/or an encapsulation layer TFE.

On the base layer BL, the first region DA (see FIG. 3) and/or the second region NDA (see FIG. 3) adjacent to the first region DA (see FIG. 3) may be defined.

On an upper surface of the base layer BL, at least one inorganic layer may be formed. The inorganic layer may include at least one of aluminum oxide, titanium oxide, silicon oxide, silicon oxynitride, zirconium oxide, and/or hafnium oxide. The inorganic layer may be formed of multiple layers. The multi-layered inorganic layers may constitute barrier layers BR1 and/or BR2 and/or a buffer layer BFL, which are to be described later. The barrier layers BR1 and/or BR2 and/or the buffer layer BFL may be selectively arranged.

The barrier layers BR1 and/or BR2 may reduce, or prevent, foreign materials from being introduced from the outside. The barrier layers BR1 and/or BR2 may include a silicon oxide layer and/or a silicon nitride layer. Each of these may be provided in plurality, and the silicon oxide layers and the silicon nitride layers may be alternately stacked.

The barrier layers BR1 and/or BR2 may include a first barrier layer BR1 and/or a second barrier layer BR2. A first rear-surface metal layer BMC1 may be arranged between the first barrier layer BR1 and the second barrier layer BR2. In some example embodiments of the inventive concepts, the rear-surface metal layer BMC1 may be omitted.

The buffer layer BFL may be arranged on the barrier layers BR1 to BR2. The buffer layer BFL may improve coupling force between the base layer BL and a semiconductor pattern and/or a conductive pattern. The buffer layer BFL may include at least one silicon oxide layer and/or at least one silicon nitride layer. The silicon oxide layer and the silicon nitride layer may be alternately stacked.

A first semiconductor pattern S1, A1, and/or D1 may be arranged on the buffer layer BFL. The first semiconductor pattern S1, A1, and/or D1 may include a silicon semiconductor. For example, the silicon semiconductor may include amorphous silicon, polycrystalline silicon, or the like. For example, the first semiconductor pattern S1, A1, and/or D1 may include low-temperature polysilicon.

FIG. 5 illustrates a portion of the first semiconductor pattern S1, A1, and/or D1 arranged on the buffer layer BFL, and other portions thereof may be further arranged in other regions. The first semiconductor pattern S1, A1, and/or D1 may be arranged according to a specific rule across pixels. The first semiconductor pattern S1, A1, and/or D1 may have different electrical properties depending on whether or not doped. The first semiconductor pattern S1, A1, and/or D1 may include first partial regions S1 and D1 having a high conductivity and/or a second partial region A1 having a low conductivity. The first partial regions S1 and/or D1 may be doped with an N-type dopant or P-type dopant. A P-type transistor may include a doped region doped with the P-type dopant, and an N-type transistor may include a doped region doped with the N-type dopant. The second partial region A1 may be a non-doped region, or may be doped to a lower concentration than that of the first partial regions S1 and/or D1.

The conductivity of the first partial regions S1 and/or D1 may be greater than the conductivity of the second partial region A1, and the first partial regions S1 and/or D1 may substantially serve as electrodes and/or signal lines. The second partial region A1 may substantially correspond to an active region (or a channel) of a transistor. In other words, a portion of a semiconductor pattern may be an active region of a transistor, another portion thereof may be a source or a drain of the transistor, and/or the other portion thereof may be a connection electrode or a connection signal line.

A first electrode S1, an active region A1, and/or a second electrode D1 of the first transistor T1 are formed from the first semiconductor pattern. The first electrode S1 and the second electrode D1 of the first transistor T1 extend in opposite directions from each other from the active region A1.

FIG. 5 illustrates a portion of a connection signal line CSL formed from the first semiconductor pattern S1, A1, and/or D1. Although not separately illustrated, the connection signal line CSL may be electrically connected to the second electrode of the seventh transistor T7 (see FIG. 4) and the second electrode of the sixth transistor T6 (see FIG. 4) on a plane.

A first insulating layer 10 may be arranged on the buffer layer BFL. The first insulating layer 10 commonly overlaps a plurality of pixels, and may cover the first semiconductor pattern S1, A1, and/or D1. The first insulating layer 10 may be an inorganic layer and/or an organic layer, and may have a single-layered or multi-layered structure. The first insulating layer 10 may include at least one of aluminum oxide, titanium oxide, silicon oxide, silicon nitride, silicon oxynitride, zirconium oxide, and/or hafnium oxide. In some example embodiments, the first insulating layer 10 may be a single-layered silicon oxide layer. Not only the first insulating layer 10 but also an insulating layer of the circuit layer DP_CL to be described later may be an inorganic layer and/or an organic layer, and may have a single-layered or multi-layered structure. The inorganic layer may include at least one of the above-described materials, but example embodiments are not limited to this example.

A third electrode G1 of the first transistor T1 is arranged on the first insulating layer 10. The third electrode G1 may be a portion of a metal pattern. The third electrode G1 of the first transistor T1 overlaps the active region A1 of the first transistor T1. In a process of doping the first semiconductor pattern S1, A1, and/or D1, the third electrode G1 of the first transistor T1 may function as a mask. The third electrode G1 may include titanium (Ti), silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), indium tin oxide (ITO), indium zinc oxide (IZO), or the like, but example embodiments are not limited to this example.

A second insulating layer 20 is arranged on the first insulating layer 10, and may cover the third electrode G1 on the first transistor T1. The second insulating layer 20 may be an inorganic layer and/or an organic layer, and may have a single-layered or a multi-layered structure. The second insulating layer 20 may include at least one of silicon oxide, silicon nitride, and/or silicon oxynitride. In some example embodiments, the second insulating layer 20 may have a multi-layered structure including a silicon oxide layer and/or a silicon nitride layer.

An upper electrode UE and/or a second rear-surface metal layer BMC2 may be arranged on the second insulating layer 20. The upper electrode UE may overlap the third electrode G1. The upper electrode UE may be a portion of a metal pattern. A portion of the third electrode G1 and/or the upper electrode UE overlapping the portion of the third electrode G1 may define the capacitor Cst (see FIG. 4). In some example embodiments of the inventive concepts, the second insulating layer 20 may be replaced with an insulating pattern. In this case, the upper electrode UE may be arranged on the insulating pattern, and the upper electrode UE may serve as a mask which forms the insulating pattern from the second insulating layer 20.

The second rear-surface metal layer BMC2 may be arranged to correspond to a lower portion of an oxide thin film transistor, e.g., the third transistor T3. The second rear-surface metal layer BMC2 may be applied with a constant voltage or a signal.

A third insulating layer 30 is arranged on the second insulating layer 20, and may cover the upper electrode UE and/or the second rear-surface metal layer BMC2. The third insulating layer 30 may have a single-layered or multi-layered structure. For example, the third insulating layer 30 may have a multi-layered structure including a silicon oxide layer and/or a silicon nitride layer.

A second semiconductor pattern S3, A3, and/or D3 may be arranged on the third insulating layer 30. The second semiconductor pattern S3, A3, and/or D3 may include an oxide semiconductor. The oxide semiconductor may include a plurality of regions distinguished according to whether a metal oxide has been reduced or not. A region in which the metal oxide has been reduced (hereinafter, a reduction region) has greater conductivity than a region in which the metal oxide has not been reduced (hereinafter, a non-reduction region). The reduction regions S3 and/or D3 substantially serve as a source/drain of a transistor or a signal line. The non-reduction region A3 may substantially correspond to an active region (or a semiconductor region or a channel) of the transistor. In other words, a portion of the second semiconductor pattern S3, A3, and/or D3 may be an active region of a transistor, another portion thereof may be a source/drain region of the transistor, and/or the other portion thereof may be a signal transfer region.

A first electrode S3, an active region A3, and/or a second electrode D3 of the third transistor T3 are formed from the second semiconductor pattern S3, A3, and/or D3. The first electrode S3 and/or the second electrode D3 include a metal reduced from a metal oxide semiconductor. The first electrode S3 and the second electrode D3 may extend in opposite directions from each other from the active region A3 on a cross-section.

A fourth insulating layer 40 may be arranged on the third insulating layer 30. The fourth insulating layer 40 commonly overlaps a plurality of pixels, and may cover the second semiconductor pattern S3, A3, and/or D3. The fourth insulating layer 40 may include at least one of aluminum oxide, titanium oxide, silicon oxide, silicon nitride, silicon oxynitride, zirconium oxide, and/or hafnium oxide.

A third electrode G3 of the third transistor T3 is arranged on the fourth insulating layer 40. The third electrode G3 may be a portion of a metal pattern. The third electrode G3 of the third transistor T3 overlaps the active region A3 of the third transistor T3. In a process of reducing the second semiconductor pattern S3, A3, and/or D3, the third electrode G3 may serve as a mask. In some example embodiments of the inventive concepts, the fourth insulating layer 40 may be replaced with an insulating pattern.

A fifth insulating layer 50 is arranged on the fourth insulating layer 40, and may cover the third electrode G3. The fifth insulating layer 50 may be an inorganic layer.

A first connection electrode CNE10 may be arranged on the fifth insulating layer 50. The first connection electrode CNE10 may be connected to the connection signal line CSL through a first contact-hole CH1 penetrating the first to fifth insulating layers 10, 20, 30, 40, and/or 50.

A sixth insulating layer 60 may be arranged on the fifth insulating layer 50. The sixth insulating layer 60 may be an organic layer. The organic layer may include a general purpose polymer such as benzocyclobutene (BCB), polyimide, hexamethyldisiloxane (HMDSO), polymethylmethacrylate (PMMA), and polystyrene (PS), a polymer derivative having a phenolic group, an acrylic polymer, an imide-based polymer, an aryl ether-based polymer, an amide-based polymer, a fluorine-based polymer, a p-xylene-based polymer, a vinyl alcohol-based polymer, a blend thereof, or the like, but example embodiments are not limited to this example.

A second connection electrode CNE20 may be arranged on the sixth insulating layer 60. The second connection electrode CNE20 may be connected to the first connection electrode CNE10 through a second contact-hole CH2 penetrating the sixth insulating layer 60. A seventh insulating layer 70 is arranged on the sixth insulating layer 60, and may cover the second connection electrode CNE20. The seventh insulating layer 70 may be an organic layer.

The element layer DP_ED may be arranged on the circuit layer DP_CL. The element layer DP_ED may include or plurality of emission elements EE. In FIG. 5, one emission element EE is representatively illustrated.

An emission region PXA may be defined corresponding to the emission element EE. The emission region PXA may be defined by a pixel defining layer PDL to be described later.

The emission element EE may include a first electrode AE, a first functional layer HFL, an emission layer EL, a second functional layer EFL, and/or a second electrode CE. The first functional layer HFL, the second functional layer EFL, and/or the second electrode CE may be commonly provided to the pixels PX (see FIG. 3).

Referring to FIG. 5, the first electrode AE of the emission element EE may be arranged on the seventh insulating layer 70. The first electrode AE of the emission element EE may be connected to the second connection electrode CNE20 through a third contact-hole CH3 penetrating the seventh insulating layer 70.

The emission element EE may further include an auxiliary layer SLA. The auxiliary layer SLA may be arranged in the emission region PXA. The auxiliary layer SLA may be arranged between the first functional layer HFL and the emission layer EL. In some example embodiments of the inventive concepts, the auxiliary layer SLA may be omitted.

The pixel defining layer PDL is arranged on the seventh insulating layer 70, and may cover a portion of the first electrode AE. A plurality of emission openings PDLop1 are provided in the pixel defining layer PDL. A plurality of emission regions PXA may be defined by the emission openings PDLop1.

The emission region PXA may be defined by the emission opening PDLop1. The emission opening PDLop1 may expose at least a portion of the first electrode AE of the emission element EE.

In some example embodiments of the inventive concepts, the pixel defining layer PDL may further include a black material. The pixel defining layer PDL may further include carbon black, and/or a black organic dye/pigment such as aniline black. The pixel defining layer PDL may be formed by mixing a blue organic material and a black organic material. The pixel defining layer may further include a liquid-repellent organic material.

The emission layer EL of the emission element EE may be arranged in a region corresponding to the emission opening PDLop1. The emission layer EL may generate color light of a predetermined, or alternately given, color. Although a patterned emission layer EL has been described as an example, in some example embodiments one emission layer may be commonly arranged in a plurality of emission regions. For example, the emission layer may generate white light or blue light. For example, the emission layer may have a multi-layered structure referred to as a tandem.

The emission layer EL may include a low-molecular organic material and/or a polymer organic material as an emission material. Alternatively, the emission layer EL may include a quantum dot material as the emission material. A core of the quantum dot may be selected from a Group II-VI compound, a Group III-V compound, a Group IV-VI compound, a Group IV element, a Group IV compound, and/or a combination thereof.

The element layer DP_ED may further include a capping layer arranged on the second electrode CE. The capping layer may serve to improve emission efficiency by the principle of constructive interference. The capping layer may include, e.g., a material having a refractive index of 1.6 or greater with respect to light having a wavelength of 589 nm. The capping layer may be an organic capping layer including an organic material, an inorganic capping layer including an inorganic material, and/or a composite capping layer including an organic material and an inorganic material. For example, the capping layer may include a carbocyclic compound, a heterocyclic compound, an amine group-containing compound, a porphyrin derivative, a phthalocyanine derivative, a naphthalocyanine derivative, an alkali metal complex, an alkaline earth metal complex, and/or any combination thereof. The carbocyclic compound, the heterocyclic compound, and/or the amine group-containing compound may optionally be substituted with a substituent including O, N, S, Se, Si, F, Cl, Br, I, and/or any combination thereof.

The encapsulation layer TFE is arranged on the element layer DP_ED. The encapsulation layer TFE includes at least an inorganic layer or an organic layer. In some example embodiments of the inventive concepts, the encapsulation layer TFE may include two inorganic layers and an organic layer arranged therebetween. In some example embodiments of the inventive concepts, the thin film encapsulation layer may include a plurality of inorganic layers and a plurality of organic layers, which are alternately stacked.

The encapsulation inorganic layer protects the emission element EE from moisture/oxygen, and the encapsulation organic layer protects the emission element EE from foreign materials such as dust particles. The encapsulation inorganic layer may include a silicon nitride layer, a silicon oxynitride layer, a silicon oxide layer, a titanium oxide layer, an aluminum oxide layer, and/or the like, but example embodiments are not limited to this example. The encapsulation organic layer may include an acrylic organic layer, but example embodiments are not limited to this example.

The panel DP may further include the sensor layer 200, and/or the reflection prevention layer 300.

The sensor layer 200 may be arranged on the display layer 100. The sensor layer 200 may sense an external input applied from the outside. The external input may be a user input. The user input may include various forms of external inputs, such as a part of a user's body, light, heat, a pen, and/or pressure. The sensor layer 200 may be referred to as a sensor, an input sensing layer, and/or an input sensing panel. The sensor layer 200 may include a sensor base layer 201, a first sensor conductive layer 202, an interlayer insulating layer 203, a second sensor conductive layer 204, and/or a cover layer 205.

The sensor base layer 201 may be directly arranged on the display layer 100. The sensor base layer 201 may be an inorganic layer including at least one of silicon nitride, silicon oxynitride, and/or silicon oxide. Alternatively, the sensor base layer 201 may be an organic layer including an epoxy resin, an acrylic resin, or an imide-based resin. The sensor base layer 201 may have a single-layered structure, and/or a multi-layered structure in which layers are stacked along the third direction DR3.

The first sensor conductive layer 202 and/or the second sensor conductive layer 204 may each have a single-layered structure, or a multi-layered structure in which layers are stacked along the third direction DR3.

A conductive layer of a single-layered structure may include a metal layer and/or a transparent conductive layer. The metal layer may include molybdenum, silver, titanium, copper, aluminum, and/or an alloy thereof. The transparent conductive layer may include a transparent conductive oxide such as indium tin oxide, indium zinc oxide, zinc oxide, and/or indium tin zinc oxide. For example, the transparent conductive layer may include a conductive polymer such as PEDOT, a metal nanowire, graphene, and/or the like.

A conductive layer of a multi-layered structure may include metal layers. The metal layers may have, for example, a three-layered structure of titanium/aluminum/titanium. The conductive layer of a multi-layered structure may include at least one metal layer and/or at least one transparent conductive layer.

The interlayer insulating layer 203 may be arranged between the first sensor conductive layer 202 and the second sensor conductive layer 204. The interlayer insulating layer 203 may include an inorganic layer. The inorganic layer may include at least one of aluminum oxide, titanium oxide, silicon oxide, silicon nitride, silicon oxynitride, zirconium oxide, and/or hafnium oxide.

In some example embodiments, the interlayer insulating layer 203 may include an organic layer. The organic layer may include at least one of an acrylic resin, a methacrylic resin, polyisoprene, a vinyl-based resin, an epoxy-based resin, a urethane-based resin, a cellulose-based resin, a siloxane-based resin, a polyimide-based resin, a polyamide-based resin, and/or a perylene-based resin.

The cover layer 205 is arranged on the interlayer insulating layer 203 and may cover the second sensor conductive layer 204. The second sensor conductive layer 204 may include a conductive pattern. The cover layer 205 covers the conductive pattern, and may reduce or eliminate the probability of damage to the conductive pattern in a subsequent process. The cover layer 205 may include an inorganic material. For example, the cover layer 205 may include silicon nitride, but example embodiments are not limited to this example. In some example embodiments of the inventive concepts, the cover layer 205 may be omitted.

The reflection prevention layer 300 may be arranged on the sensor layer 200. The reflection prevention layer 300 may include a partition layer 310, a plurality of color filters 320, and/or a planarization layer 330.

The partition layer 310 may be arranged overlapping the conductive pattern of the second sensor conductive layer 204. The cover layer 205 may be arranged between the partition layer 310 and the second sensor conductive layer 204. The partition layer 310 may reduce, or prevent, external light reflection by the second sensor conductive layer 204. A material constituting the partition layer 310 is not particularly limited as long as it is a material which absorbs light. The partition layer 310 is a layer having a black color, and in some example embodiments, the partition layer 310 may include a black coloring agent. The black coloring agent may include a black dye and/or a black pigment. The black coloring agent may include carbon black, a metal such as chromium, and/or an oxide thereof.

A plurality of partition openings may be defined in the partition layer 310. The plurality of partition openings may each overlap the emission layer EL and/or a photoelectric conversion layer. The color filters 320 may be arranged corresponding to the plurality of partition openings. The color filter 320 may transmit light provided from the emission layer EL overlapping the color filter 320.

The planarization layer 330 may cover the partition layer 310 and the color filters 320. The planarization layer 330 may include an organic material, and may provide a flat surface on an upper surface of the planarization layer 330. In some example embodiments, the planarization layer 330 may be omitted.

In some example embodiments of the inventive concepts, the reflection prevention layer 300 may include a reflection adjustment layer 321 instead of the color filters 320. The reflection adjustment layer 321 may selectively absorb light reflected from the inside of a display panel and/or an electronic device, and/or light of some bandwidths among light incident from the outside of the display panel DP and/or the electronic device ED.

According to some example embodiments, the reflection adjustment layer 321 may absorb light of a first wavelength region of approximately 490 nm to approximately 505 nm and/or light of a second wavelength region of approximately 585 nm to 600 nm, and thus, may be provided to have a light transmittance of approximately 40% or less in the first wavelength region and/or the second wavelength region. The reflection adjustment layer 321 may absorb light of a wavelength which is out of wavelength ranges of red, green, and/or blue light emitted from the emission layer EL. As described above, since the reflection adjustment layer 321 absorbs light of a wavelength which does not belong to a wavelength range of red, green, and/or blue light emitted from the emission layer EL, a decrease in luminance of the display panel and/or the electronic device may be reduced, prevented, or minimized. In addition, at the same time, degradation in luminescence efficiency of the display panel and/or the electronic device may be reduced, prevented, or minimized, and visibility may be improved.

The reflection adjustment layer 321 may be provided as an organic matter layer including a dye, a pigment, and/or a combination thereof. The reflection adjustment layer 321 may include a tetraazaporphyrin (TAP)-based compound, a porphyrin-based compound, a metal porphyrin-based compound, an oxazine-based compound, a squarylium-based compound, triarylmethane-based compound, a polymethine-based compound, an anthraquinone-based compound, a phthalocyanine-based compound, an azo-based compound, a perylene-based compound, a xanthene-based compound, a diimmonium-based compound, a dipyrromethene-based compound, a cyanine-based compound, and/or a combination thereof.

In some example embodiments, the reflection adjustment layer 321 may have a transmittance of approximately 64% to approximately 72%. The transmittance of the reflection adjustment layer 321 may be adjusted according to the content of a pigment and/or a dye included in the reflection adjustment layer 321.

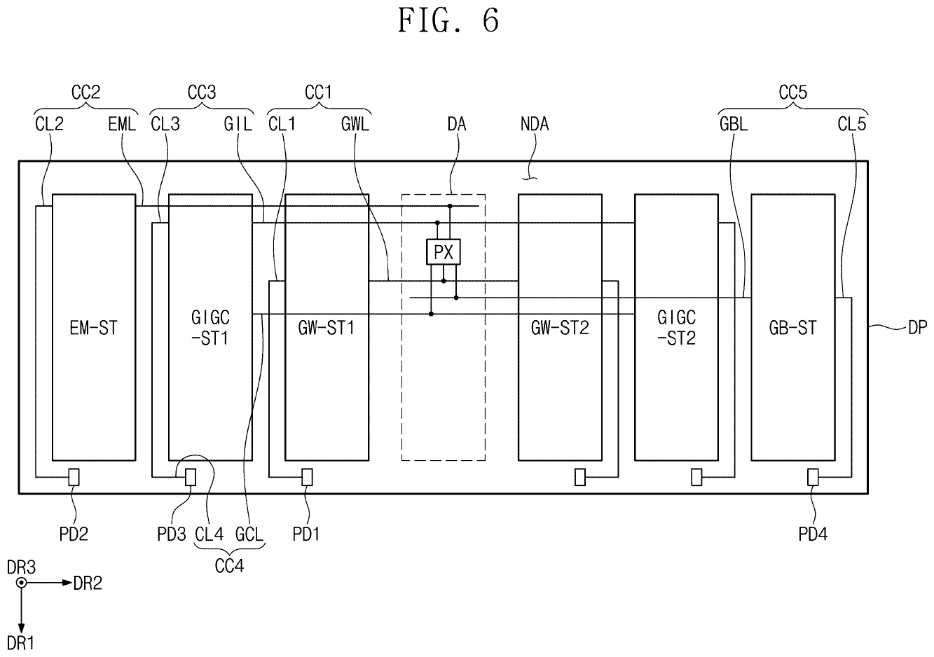

FIG. 6 is a schematic block diagram of the display panel DP according to some example embodiments of the inventive concepts.

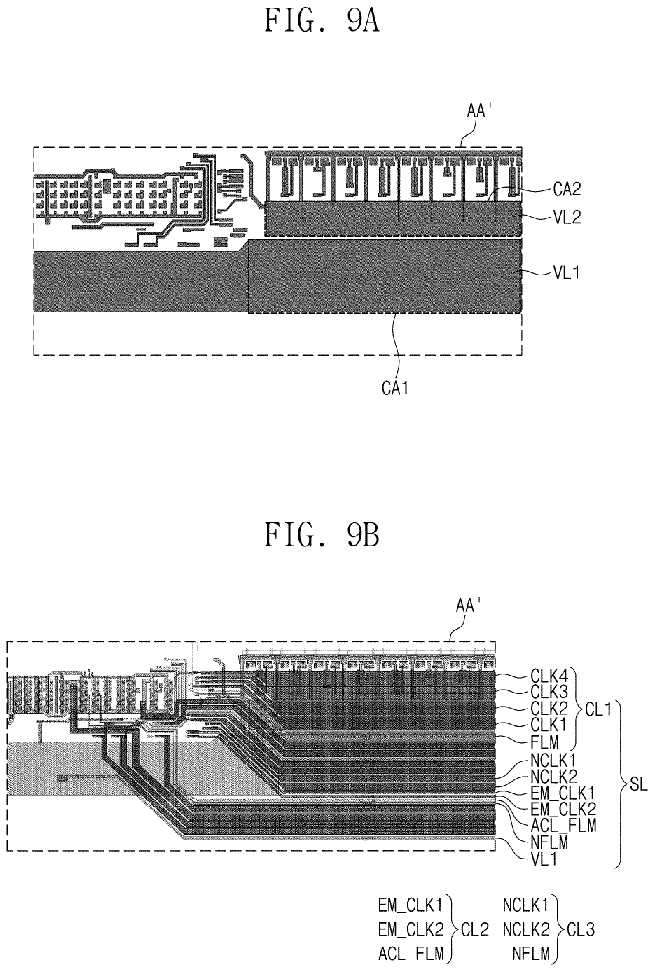

Referring to FIG. 3 and FIG. 6, the display panel DP may include a plurality of stages and/or a plurality of signal lines SL (see FIG. 9B). In FIG. 6, a plurality of stages electrically connected to one pixel PX and a plurality of signal lines SL (see FIG. 9B) electrically connected to the stages are illustrated as an example.

The plurality of stages may include a 1-1-th GW-ST1, a 1-2-th stage GW-ST2, a second stage EM-ST, a 3-1-th stage GIGC-ST1, a 3-2-th stage GIGC-ST2, and/or a fourth stage GB-ST.

In some example embodiments of the inventive concepts, the 1-1-th GW-ST1 and/or the 3-1-th stage GIGC-ST1 may be included in the first scan driving circuit SDC1, and the 1-2-th stage GW-ST2, the 3-2-th stage GIGC-ST2, and/or the fourth stage GB-ST may be included in the second scan driving circuit SDC2. The second stage EM-ST may be included in the emission driving circuit EDC.

The plurality of signal lines SL (see FIG. 9B) may include a first signal line CL1, a second signal line CL2, a third signal line CL3, a fourth signal line CL4, and/or a fifth signal line CL5. In some example embodiments of the inventive concepts, the third signal line CL3 and the fourth signal line CL4 may be the same line. Therefore, one signal line may be referred to as the third signal line CL3 or the fourth signal line CL4.

The signal lines CL1, CL2, CL3, CL4, and/or CL5 may each, or one or more, be electrically connected to a plurality of pads PD1, PD2, PD3, and/or PD4. The plurality of pads PD1, PD2, PD3, and/or PD4 may each, or one or more, output a plurality of signals including a clock signal to the signal lines CL1, CL2, CL3, CL4, and/or CL5.

The 1-1-th stage GW-ST1 may be electrically connected to the first signal line CL1 and/or a first scan line GWL. The 1-1-th stage GW-ST1, the first signal line CL1, and/or the first scan line GWL may be referred to as one circuit, that is, a first circuit CC1. Therefore, the first circuit CC1 may include the 1-1-th stage GW-ST1, the first signal line CL1, and/or the first scan line GWL. In some example embodiments, the 1-2-th stage GW-ST2 may have the same configuration as that of the 1-1-th stage GW-ST1. The 1-1-th stage GW-ST1 and/or the 1-2-th stage GW-ST2 may be referred to as a first stage.

The second stage EM-ST may be electrically connected to the second signal line CL2 and/or the emission control line EML. The second stage EM-ST, the second signal line CL2, and/or the emission control line EML may be referred to as one circuit, that is, a second circuit CC2. Therefore, the second circuit CC2 may include the second stage EM-ST, the second signal line CL2, and/or the emission control line EML.

In some example embodiments of the inventive concepts, the 3-1-th stage GIGC-ST1 may be electrically connected to the third signal line CL3 and/or the fourth signal line CL4, and the 3-1-th stage GIGC-ST1 may be electrically connected to a second scan line GIL and/or a third scan line GCL.

Although FIG. 6 illustrates an example in which the second scan line GIL and the third scan line GCL are electrically connected to one stage GIGC-ST1, some example embodiments of the inventive concept are not limited to this example, and the second scan line GIL and/or the third scan line GCL may be electrically connected to different stages, respectively. Therefore, although FIG. 6 illustrates an example in which one signal line is referred to as the third signal line CL3 or the fourth signal line CL4, if the second scan line GIL and the third scan line GCL are electrically connected to different stages, respectively, the third signal line CL3 and the fourth signal line CL4 may be lines different from each other.

The 3-1-th stage GIGC-ST1, the third signal line CL3, and/or the second scan line GIL may be referred to as one circuit, that is, a third circuit CC3. Therefore, the third circuit CC3 may include the 3-1-th stage, the third signal line CL3, and/or the second scan line GIL. The 3-1-th stage GIGC-ST1, the fourth signal line CL4, and/or the third scan line GCL may be referred to as one single circuit, that is, a fourth circuit CC4. Therefore, the fourth circuit CC4 may include the 3-1-th stage GIGC-ST1, the fourth signal line CL4, and/or the third scan line GCL. In some example embodiments, the 3-2-th stage GIGC-ST2 may have the same configuration as that of the 3-1-th stage GIGC-ST1. The 3-1-th stage GIGC-ST1 and/or the 3-2-th stage GIGC-ST2 may be referred to as a third stage.

The fourth stage GB-ST may be electrically connected to the fifth signal line CL5 and/or a fourth scan line GBL. The second stage GB-ST, the fifth signal line CL5, and/or the fourth scan line GBL may be referred to as one circuit, that is, a fifth circuit CC5. Therefore, the fifth circuit CC5 may include the fourth stage GB-ST, the fifth signal line CL5, and/or the fourth scan line GBL.

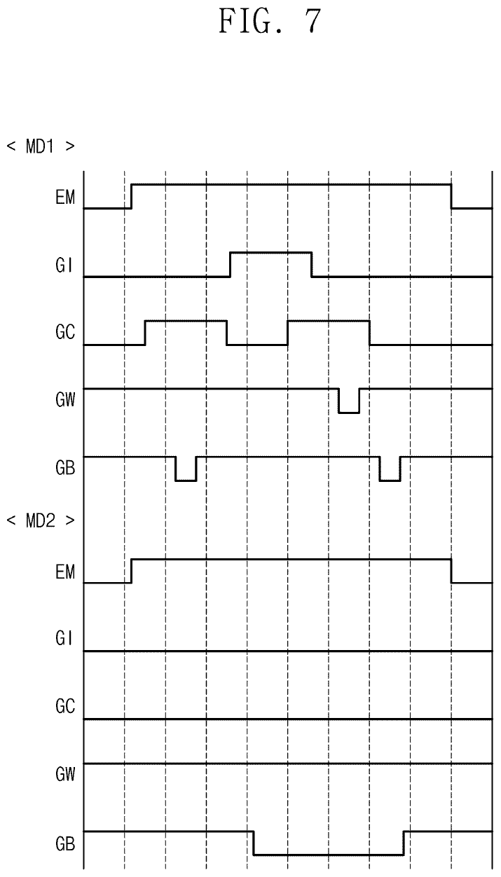

FIG. 7 is a timing diagram showing signals according to some example embodiments of the inventive concepts.

FIG. 7 illustrates the waveform of each of an emission signal EM, a first scan signal GW, a second scan signal GI, a third scan signal GC, and a fourth scan signal GB corresponding to each period.

Referring to FIG. 4, FIG. 6, and FIG. 7, the display panel DP may be driven at various driving frequencies. For example, the display panel DP may operate at a predetermined, or alternately given, driving frequency, e.g., 60 Hz, 120 Hz, or 240 Hz. In addition, the display panel DP may operate in a low scan-rate mode in which the display panel DP is driven at a frequency of tens of Hz or less. For example, in an always on display (AOD) mode, the display panel DP may operate in a low scan-rate mode. In some example embodiments, the display panel DP may be driven at a variable driving frequency. For example, the variable driving frequency may be variously changed within a range of 1 Hz to 240 Hz, but the range of a driving frequency is not particularly limited to the above-described example.

One frame of the display panel DP may include a plurality of periods MD1 and/or MD2. The periods MD1 and/or MD2 may include a data write period MD1 and/or a self-period MD2. The data write period MD1 may be referred to as an address period, an address cycle, and/or a data write cycle, and the self-period MD2 may be referred to as a hold period, a hold cycle, and/or a self-cycle.

If the display panel DP is driven at 120 Hz, one frame may include one data write period MD1 and/or one self-period MD2. If the display panel DP is driven at 48 Hz, one frame may include one data write period MD1 and/or four self-periods MD2. However, this is merely an example for describing that the number of self-periods MD2 included in one frame increases as the driving frequency of the display panel DP decreases, and some example embodiments of the inventive concepts are not limited to this example.

The pixel circuit PXC (see FIG. 4) may be configured to operate in response to the data write period MD1 and/or the self-period MD2. Hereinafter, the operation of the pixel circuit PXC in the data write period MD1 and the self-period MD2 will be described.

In the data write period MD1, the level of each, or one or more, of the emission signal EM, the first scan signal GW, the second scan signal GI, the third scan signal GC, and/or the fourth scan signal GB may be changed.

In a logic-high level period of the third scan signal GC, the third transistor T3 may be turned on. The first transistor T1 may be diode-connected by the turned-on third transistor T3. The logic-high level period of the third scan signal GC may be a compensation period for compensating for a threshold voltage of the first transistor T1.

In a logic-high level period of the second scan signal GI, the fourth transistor T4 may be turned on. The first initialization voltage VINT1 may be transferred to the gate electrode of the first transistor T1 through the fourth transistor T4, and the first transistor T1 may be initialized. The logic-high level period of the second scan signal GI may be an initialization period for initializing a voltage level of the gate electrode of the first transistor T1.

In a logic-low level period of the first scan signal GW, the second transistor T2 is turned on, and the data signal Di may be transferred to the first electrode of the first transistor T1 through the second transistor T2.

In a logic-low level period of the fourth scan signal GB, the seventh transistor T7 is turned on, and the second initialization voltage VINT2 may be transferred to the anode of the emission element EE through the seventh transistor T7. Although FIG. 7 illustrates an example in which the fourth scan signal GB is activated to a logic low level two times, example embodiments are not limited to this example and the fourth scan signal GB may be activated one time or two or more times.

Thereafter, in a logic-low level period of the emission signal EM, the fifth transistor T5 and/or the sixth transistor T6 may be turned on. A current path may be formed between the second driving voltage line VL2 and the emission element EE through the fifth transistor T5, the second transistor T2, and/or the sixth transistor T6. Then, a driving current Id, which flows according to a difference between the voltage of the gate electrode of the first transistor T1 and the voltage of the second driving voltage ELVDD, is generated, and the driving current Id is supplied to the emission element EE, so that the emission element EE may emit light.

In this case, a logic-high level period of the emission signal EM may overlap the logic-high level period of each, or one or more, of the first scan signal GW, the second scan signal GI, the third scan signal GC, and/or the fourth scan signal GB.

In the self-period MD2, the level of each, or one or more, of the emission signal EM and/or the fourth scan signal GB may be changed, and the level of each, or one or more, of the first scan signal GW, the second scan signal GI, and/or the third scan signal GC may be maintained. For example, the first scan signal GW may maintain a logic-high level, and the second scan signal GI and/or the third scan signal GC may maintain a logic-low level. Therefore, in the self-period MD2, the second transistor T2, the third transistor T3, and/or the fourth transistor T4 may maintain a turn-off state.

In the self-period MD2, the anode of the emission element EE may be initialized in the logic-low level period of the fourth scan signal GB, and in the logic-low level period of the emission signal EM, the fifth transistor T5 and/or the sixth transistor T6 may be turned on. A current path may be formed between the second driving voltage line VL2 and the emission element EE through the fifth transistor T5, the second transistor T2, and/or the sixth transistor T6. Then, a driving current Id, which flows according to a difference between the voltage of the gate electrode of the first transistor T1 and the voltage of the second driving voltage ELVDD, is generated, and the driving current Id is supplied to the emission element EE, so that the emission element EE may emit light.

Unlike the first scan signal GW, the second scan signal GI, and/or the third scan signal GC, the level of the emission signal EM and/or the fourth scan signal GB may be changed in the self-period MD2 as well as in the data write period MD1. The load of the second circuit CC2 which generates and transfers the emission signal EM and/or the load of the fifth circuit CC5 which generates and transfers the fourth scan signal GB may be designed to be smaller than each, or one or more, of the load of the first circuit CC1 which generates and transfers the first scan signal GW, the load of the third circuit CC3 which generates and transfers the second scan signal GI, and/or the load of the fourth circuit CC4 which generates and transfers the third scan signal GC. The load of each, or one or more, circuit may include various loads such as a resistive load, a capacitive load, and the like. For example, since the load of the second circuit CC2 and the load of the fifth circuit CC5 are designed to be relatively small even when the level of the emission signal EM and the level of the fourth scan signal GB are more frequently changed in a low scan-rate mode, the power consumption by the charge-discharge of the capacitive load may be reduced, and as a result, the power consumption of the electronic device ED (see FIG. 1) may be reduced.

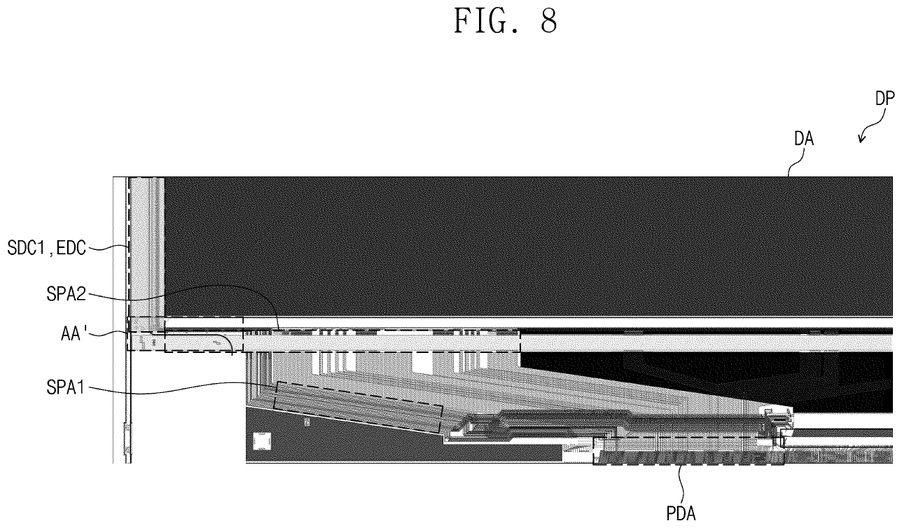

FIG. 8 is a plan view of a portion of the display panel DP according to some example embodiments of the inventive concepts. FIG. 9A is an enlarged plan view of region AA′ of FIG. 8 according to some example embodiments of the inventive concept. FIG. 9B is an enlarged plan view of region AA′ of FIG. 8 according to some example embodiments of the inventive concepts.

Referring to FIG. 6, FIG. 8, FIG. 9A, and FIG. 9B, the display panel DP may include a pad region PDA, a first line region SPA1, and/or a second line region SPA2.

The region AA′ illustrated in FIG. 9A and FIG. 9B is a region including a portion of each, or one or more, of the first scan driving circuit SDC1 and/or the emission driving circuit EDC, and/or a portion of the second line region SPA2. In some example embodiments, the first line region SPA1 may be referred to as a first spider region SPA1, and the second line region SPA2 may be referred to as a second spider region SPA2.

The pad region PDA may be a region which outputs a plurality of signals and/or a plurality of voltages respectively corresponding to a plurality of signal lines SL and/or a plurality of driving voltage lines VL1 and/or VL2. The signal lines SL may include a first signal line CL1, a second signal line CL2, a third signal line CL3, and/or a fourth signal line CL4.

In some example embodiments of the inventive concepts, the first signal line CL1 may include four clock lines CLK1, CLK2, CLK3, and/or CLK4 and/or an initiation signal line FLM which correspond to the 1-1 stage GW-ST1. The second signal line CL2 may include two clock lines EM_CLK1 and/or EM_CLK2 and/or an initiation signal line ACL_FLM which correspond to the second stage EM-ST. The third signal line CL3 may include two clock lines NCLK1 and/or NCLK2 and/or an initiation signal line NFLM which correspond to the 3-1-th stage GIGC-ST1.

In some example embodiments of the inventive concepts, the fourth signal line CL4 may be the same line as the third signal line CL3. In addition, although not illustrated, the fifth signal line CL5 may also include clock lines and/or an initiation signal line which correspond to the fourth stage GB-ST.

Signals output from the pad region PDA may be transferred to the first scan driving circuit SDC1, the second scan driving circuit SDC2 (see FIG. 3), the emission driving circuit EDC, and/or the display region DA via the first line region SPA1 and/or the second line region SPA2 through corresponding signal lines SL, respectively.

In some example embodiments of the inventive concepts, the second line region SPA2 may be a region in which the signal lines SL and the driving voltage lines VL1 and/or VL2 overlap on a plane. The first driving voltage line VL1 may include a first overlapping portion CA1 which overlaps the signal lines SL on a plane, and the second driving voltage line VL2 may include a second overlapping portion CA2 which overlaps the signal lines SL on a plane.

The first driving voltage line VL1 and/or the second driving voltage line VL2 illustrated in FIG. 9A may be arranged at a same layer as the first connection electrode CNE10 illustrated in FIG. 5. Although not illustrated, in some example embodiments, the first driving voltage line VL1 may include a plurality of layers. For example, the first driving voltage line VL1 may include a first layer driving voltage line arranged at a same layer as the third electrode G1 of the first transistor T1 and/or a second layer driving voltage line arranged at a same layer as the first connection electrode CNE10. The first layer driving voltage line and the second layer driving voltage line may be electrically connected to each other.

The signal lines SL illustrated in FIG. 9B may be arranged at the same first layer as the third electrode G1 of the first transistor T1 illustrated in FIG. 5, the same second layer as the upper electrode UE, and/or the same third layer as the third electrode G3 of the third transistor T3. Some signal lines among the signal lines SL may include a plurality of layers, and the plurality of layers may be at least two layers among the first to third layers.

As described above, the first driving voltage line VL1 and/or the second driving voltage line VL2 illustrated in FIG. 9A and the signal lines SL illustrated in FIG. 9B may be arranged overlapping a plurality of layers on a plane. Therefore, a parasitic capacitance may be generated due to the overlapping between the signal lines SL and the driving voltage lines VL1 and VL2 in the second line region SPA2.

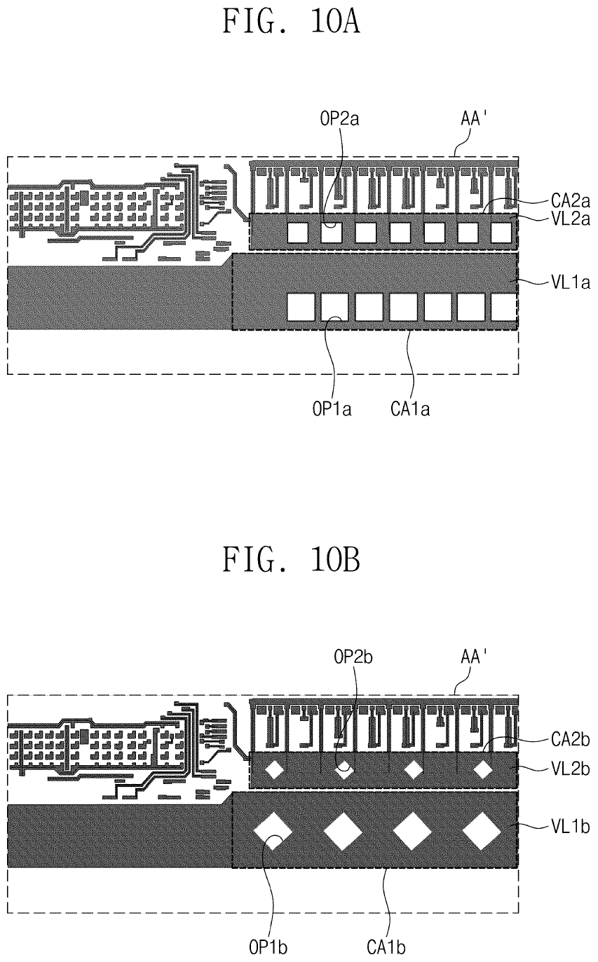

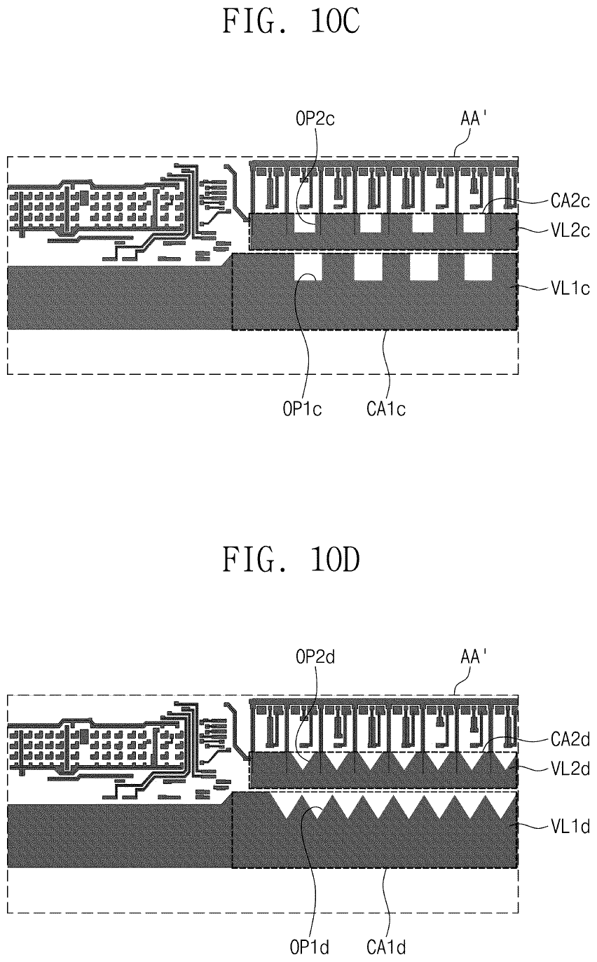

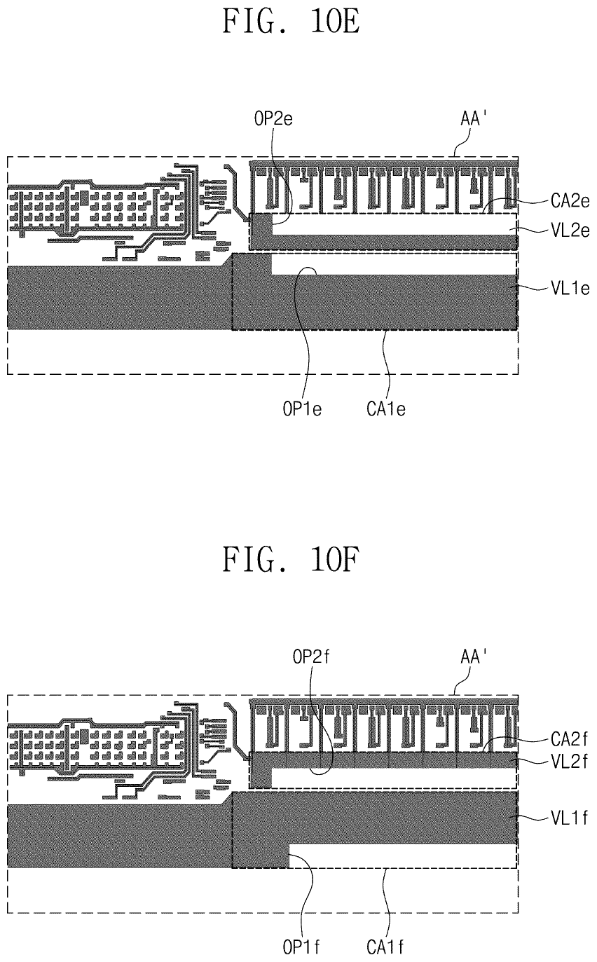

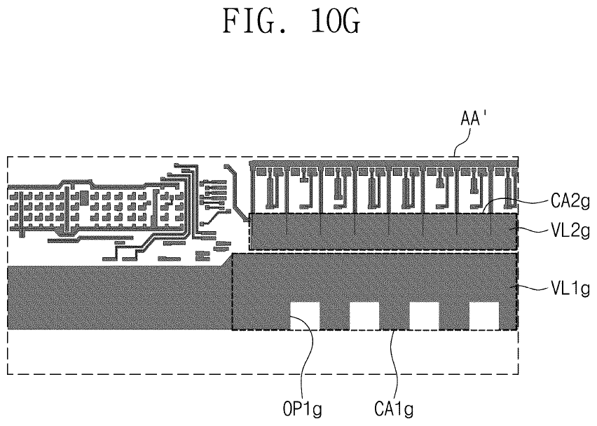

FIG. 10A is an enlarged plan view of region AA′ of FIG. 8 according to some example embodiments of the inventive concepts.

Referring to FIG. 10A, a first opening OP1a may be defined in a first overlapping portion CA1a of a first driving voltage line VL1a. A second opening OP2a may be defined in a second overlapping portion CA2a of a second driving voltage line VL2a. The first opening OP1a and/or the second opening OP2a may each be referred to as an opening.

In some example embodiments of the inventive concepts, the first opening OP1a and/or the second opening OP2a may be provided in plurality. The plurality of first openings OP1a and/or the plurality of second openings OP2a may have a quadrangular shape. When viewed on a plane, the first openings OP1a may be defined in a portion adjacent to the center of the first driving voltage line VL1a. For example, four sides of each, or one or more, of the first openings OP1a may be surrounded by the first driving voltage line VL1a. When viewed on a plane, the second openings OP2a may be defined in a portion adjacent to the center of the second driving voltage line VL2a. For example, four sides of each, or one or more, of the second openings OP2a may be surrounded by the second driving voltage line VL2a.

FIG. 10B is an enlarged plan view of region AA′ of FIG. 8 according to some example embodiments of the inventive concepts.

Referring to FIG. 10B, a first opening OP1b may be defined in a first overlapping portion CA1b of a first driving voltage line VL1b. A second opening OP2b may be defined in a second overlapping portion CA2b of a second driving voltage line VL2b.

In some example embodiments of the inventive concepts, the first opening OP1b and/or the second opening OP2b may be provided in plurality. The plurality of first openings OP1b and the plurality of second openings OP2b may have a rhombic shape. When viewed on a plane, the first openings OP1b may be defined in a portion adjacent to the center of the first driving voltage line VL1b. For example, four sides of each, or one or more, of the first openings OP1b may be surrounded by the first driving voltage line VL1b. When viewed on a plane, the second openings OP2b may be defined in a portion adjacent to the center of the second driving voltage line VL2b. For example, four sides of each, or one or more, of the second openings OP2b may be surrounded by the second driving voltage line VL2b.

FIG. 10C is an enlarged plan view of region AA′ of FIG. 8 according to some example embodiments of the inventive concepts.

Referring to FIG. 10C, a first opening OP1c may be defined in a first overlapping portion CA1c of a first driving voltage line VL1c. A second opening OP2c may be defined in a second overlapping portion CA2c of a second driving voltage line VL2c.

In some example embodiments of the inventive concepts, the first opening OP1c and/or the second opening OP2c may be provided in plurality. The plurality of first openings OP1c and/or the plurality of second openings OP2c may have a quadrangular shape. In addition, when viewed on a plane, the first openings OP1c may be defined at an upper end of the first driving voltage line VL1c. For example, the first openings OP1c may be in contact with one side of the first driving voltage line VL1c. Therefore, sides defining the first openings OP1c may be included in the outermost line of the first driving voltage line VL1c. That is, each, or one or more, of the first openings OP1c may be an open-type opening in which a portion thereof is not closed.

When viewed on a plane, the second openings OP2c may be defined at an upper end of the second driving voltage line VL2c. For example, the second openings OP2c may be in contact with one side of the second driving voltage line VL2c. Therefore, sides defining the second openings OP2c may be included in the outermost line of the second driving voltage line VL2c. That is, each, or one or more, of the second openings OP2c may be an open-type opening in which a portion thereof is not closed.

FIG. 10D is an enlarged plan view of region AA′ of FIG. 8 according some example embodiments of the inventive concepts.

Referring to FIG. 10D, a first opening OP1d may be defined in a first overlapping portion CA1d of a first driving voltage line VL1d. A second opening OP2d may be defined in a second overlapping portion CA2d of a second driving voltage line VL2d.

In some example embodiments of the inventive concepts, the first opening OP1d and/or the second opening OP2d may be provided in plurality. The plurality of first openings OP1d and/or the plurality of second openings OP2d may have a triangular shape. In addition, when viewed on a plane, the first openings OP1d may be defined at an upper end of the first driving voltage line VL1d. For example, the first openings OP1d may be in contact with one side of the first driving voltage line VL1d. Therefore, sides defining the first openings OP1d may be included in the outermost line of the first driving voltage line VL1d. That is, each, or one or more, of the first openings OP1d may be an open-type opening in which a portion thereof is not closed.

When viewed on a plane, the second openings OP2d may be defined at an upper end of the second driving voltage line VL2d. For example, the second openings OP2d may be in contact with one side of the second driving voltage line VL2d. Therefore, sides defining the second openings OP2d may be included in the outermost line of the second driving voltage line VL2d. That is, each, or one or more, of the second openings OP2d may be an open-type opening in which a portion thereof is not closed.

FIG. 10E is an enlarged plan view of region AA′ of FIG. 8 according to some example embodiments of the inventive concepts.

Referring to FIG. 10E, a first opening OP1e may be defined in a first overlapping portion CA1e of a first driving voltage line VL1e. A second opening OP2e may be defined in a second overlapping portion CA2e of a second driving voltage line VL2e.

In some example embodiments of the inventive concept, the first opening OP1e and/or the second opening OP2e may have an elongated quadrangular shape. Unlike in FIG. 10A to FIG. 10D, in FIG. 10E, the first opening OP1e and the second opening OP2e may each be defined as one. The size of each, or one or more, of the first opening OP1e and/or the second opening OP2e in FIG. 10E may be larger than the size of each, or one or more, of the openings in FIG. 10A to FIG. 10D.

When viewed on a plane, the first opening OP1e may be defined by removing a portion in an upper portion of the first driving voltage line VL1e. Therefore, the width of the first driving voltage line VL1e may be reduced due to the first opening OP1e. For example, the first opening OP1e may be in contact with one side of the first driving voltage line VL1e. Therefore, sides defining the first opening OP1e may be included in the outermost line of the first driving voltage line VL1e. That is, the first opening OP1e may be an open-type opening in which a portion thereof is not closed.

When viewed on a plane, the second opening OP2e may be defined by removing a portion in an upper portion of the first driving voltage line VL2e. Therefore, the width of the second driving voltage line VL2e may be reduced due to the second opening OP2e. For example, the second openings OP2e may be in contact with one side of the second driving voltage line VL2e. Therefore, sides defining the second opening OP2e may be included in the outermost line of the second driving voltage line VL2e. That is, the second opening OP2e may be an open-type opening in which a portion thereof is not closed.

FIG. 10F is an enlarged plan view of region AA′ of FIG. 8 according to some example embodiments of the inventive concepts.

Referring to FIG. 10F, a first opening OP1f may be defined in a first overlapping portion CA1f of a first driving voltage line VL1f. A second opening OP2f may be defined in a second overlapping portion CA2f of a second driving voltage line VL2f.

In some example embodiments of the inventive concepts, the first opening OP1f and/or the second opening OP2f may have an elongated quadrangular shape. As in FIG. 10E, in FIG. 10F, the first opening OP1f and/or the second opening OP2f may each be defined as one.

As in FIG. 10E, in FIG. 10F, when viewed on a plane, the first opening OP1f may be defined by removing a portion in a lower portion of the first driving voltage line VL1f. Therefore, the width of the first driving voltage line VL1f may be reduced due to the first opening OP1f. When viewed on a plane, the second opening OP2f may be defined by removing a portion in a lower portion of the second driving voltage line VL2f. Therefore, the width of the second driving voltage line VL2f may be reduced due to the second opening OP2f.

FIG. 10G is an enlarged plan view of region AA′ of FIG. 8 according to some example embodiments of the inventive concepts.

Referring to FIG. 10G, a first opening OP1g may be defined in a first overlapping portion CA1g of a first driving voltage line VL1g.

In some example embodiments of the inventive concepts, the first the opening OP1g may be provided in plurality. The plurality of first openings OP1g may have a quadrangular shape. Unlike in FIG. 10A to FIG. 10F, in FIG. 10G, the first openings OP1g may be formed only in the first driving voltage line VL1g, and openings may not be defined in the second driving voltage line VL2.

When viewed on a plane, the first openings OP1g may be defined at a lower end of the first driving voltage line VL1g. For example, the first openings OP1g may be in contact with one side of the first driving voltage line VL1g. Therefore, sides defining the first openings OP1g may be included in the outermost line of the first driving voltage line VL1g. For example, each of the first openings OP1g may be an open-type opening in which a portion thereof is not closed.

In FIG. 10A to FIG. 10G, some example embodiments are illustrated as examples, but some example embodiments of the inventive concepts are not limited thereto, and the shape and position of each, or one or more, of the first opening and/or the second opening may be variously applied, and the size of each, or one or more, of the first opening and/or the second opening may also be variously applied.

FIG. 11 is a table showing the power consumption of the display panel DP (see FIG. 3) according to some example embodiments of the inventive concepts.

In FIG. 11, the power consumption of the display panel DP (see FIG. 3) for each frequency is shown in the table. Comparative Example described in FIG. 11 is an example of the power consumption of a display panel in FIG. 9A, and Example described in FIG. 11 is an example of the power consumption of the display panel DP (see FIG. 3) in FIG. 10A.

Referring to FIG. 3, FIG. 8, FIG. 9A, FIG. 10A, and FIG. 11, as described above with reference to FIG. 9A, the first driving voltage line VL1 and/or the second driving voltage line VL2 and the signal lines SL illustrated in FIG. 9B may be arranged overlapping a plurality of layers on a plane. Therefore, a parasitic capacitance may be generated in the second line region SPA2, a region in which the first overlapping portion CA1 of the first driving voltage line VL1 and the second overlapping portion CA2 of the second driving voltage line VL2 are arranged.

The signal lines SL may include clock lines to which a clock signal is provided. Therefore, the level of a signal provided to the signal lines SL may be periodically changed. As the level of the signal provided to the signal lines SL changes, there may be power consumption by the charge-discharge of the capacitive load. According to some example embodiments of the inventive concepts, a design may be applied to reduce the capacitive load formed in the signal lines SL.

In FIG. 10A, the first opening OP1a may be defined in the first overlapping portion CA1a of the first driving voltage line VL1a, and/or the second opening OP2a may be defined in the second overlapping portion CA2a of the second driving voltage line VL2a. Therefore, a region in which the first driving voltage line VL1, the second driving voltage line VL2, and the signal lines SL overlap on a plane may be reduced. That is, in the second line area SPA2, a parasitic capacitance between the first driving voltage line VL1, the second driving voltage line VL2, and/or the signal lines SL may be reduced. In addition, a capacitive load of each, or one or more, of the signal lines SL may be reduced.

In some example embodiments of the inventive concepts, if the capacitive load formed in the signal lines SL is reduced, the power consumption by the charge-discharge of the capacitive load may be reduced, and as a result, the power consumption of the entire display panel DP may also be reduced. For example, when the display panel DP is operated at 120 Hz, the power consumption of the display panel according to Comparative Example may be measured at 217.6 mW, and the power consumption of the display panel DP according to Example may be measured at 199.9 mW. Therefore, the power consumption may be reduced by 8.2%. In addition, at 60 Hz, the power consumption may be reduced by 6.8% compared to that of Comparative Example, and at 1 Hz, the power consumption may be reduced by 3.4% compared to that of Comparative Example.

FIG. 11 illustrates the power consumption of FIG. 9A and FIG. 10A as an example, but some example embodiments of the inventive concepts are not limited thereto. For example, in the example embodiments illustrated in FIG. 10B to FIG. 10G, the parasitic capacitance of the second line area SPA2 is reduced, so that the power consumption may be reduced as in FIG. 10A.

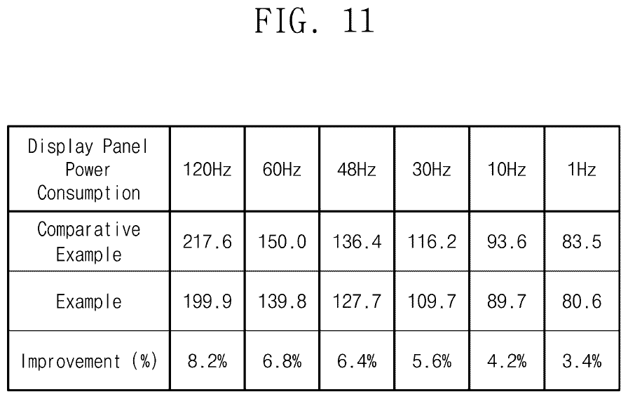

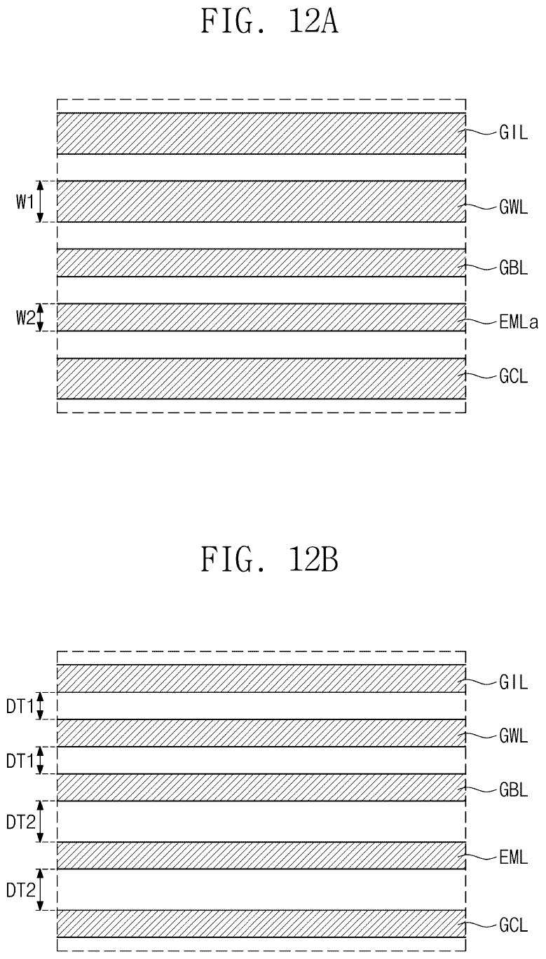

FIG. 12A is a layout of a plurality of scan lines GWL, GIL, GCL, and GBL, and an emission control line EMLa according to some example embodiments of the inventive concepts.

Referring to FIG. 6, FIG. 7, and FIG. 12A, the first to fourth scan lines GWL, GIL, GCL, and/or GBL and/or the emission control line EMLa are electrically connected to the pixel PX, and when viewed on a plane, may be arranged as shown in FIG. 12A. However, this is only an example, and the arrangement relationship of the first to fourth scan lines GWL, GIL, GCL, and/or GBL and/or the emission control line EMLa may be changed.

As described above with reference to FIG. 7, the level of signals provided to the first to fourth scan lines GWL, GIL, GCL, and/or GBL and/or the emission control line EMLa in the data write period MD1 may all, or one or more, be changed. In addition, signals provided to the first to third scan lines GWL, GIL, and GCL in the self-period MD2 may maintain a predetermined, or alternately given, level, but the level of signals provided to the emission control line EMLa and the fourth scan line GBL may be changed. If the level of a signal provided to a predetermined, or alternately given, line is changed, the power consumption may increase by the charge-discharge of a capacitive load generated in the predetermined, or alternately given, line.

In some example embodiments of the inventive concepts, in order to reduce or minimize the power consumption by the charge-discharge of a capacitive load, the capacitive load of each, or one or more, of the emission control line EMLa and/or the fourth scan line GBL may be adjusted to be smaller than the capacitive load of each, or one or more, of the first to third scan lines GWL, GIL, and/or GCL. Therefore, as the capacitive load of each, or one or more, of the emission control line EMLa and/or the fourth scan line GBL, in which the level of a signal changes more frequently is adjusted to be relatively smaller, the total power consumption of the electronic device ED (see FIG. 1) may be reduced.

In some example embodiments of the inventive concepts, in order to adjust the capacitive load, the width of each, or one or more, of the first to fourth scan lines GWL, GIL, GCL, and/or GBL and the emission control line EMLa may be adjusted. For example, the first scan line GWL may have a first width W1. The emission control line EMLa may have a second width W2. The first width W1 may be larger than the second width W2. Therefore, when the first width W1 is larger than the second width W, the capacitive load of the first scan line GWL may be larger than the capacitive load of the emission control line EMLa.

In FIG. 12A, the width of each of the first scan line GWL and the emission control line EMLa are compared as an example, but some example embodiments of the inventive concepts are not limited to this example, and the second width W2 of the emission control line EMLa may be smaller than the width of each, or one or more, of the second scan line GIL and/or the third scan line GCL. In addition, the width of the fourth scan line GBL may also be smaller than the width of each, or one or more, of the first scan line GWL, the second scan line GIL, and/or the third scan line GCL. Therefore, the capacitive load of each, or one or more, of the first scan line GWL, the second scan line GIL, and/or the third scan line GCL may be larger than the capacitive load of each, or one or more, of the emission control line EMLa and/or the fourth scan line GBL.

FIG. 12B is a layout of the plurality of scan lines GWL, GIL, GCL, and GBL, and the emission control line EML according to some example embodiments of the inventive concepts.

Referring to FIG. 6, FIG. 7, and FIG. 12B, in order to adjust the capacitive load of each, or one or more, of the first to fourth scan lines GWL, GIL, GCL, and/or GBL and/or the emission control line EML, the distance between the first to fourth scan lines GWL, GIL, GCL, and/or GBL and/or the emission control line EML may be adjusted.

For example, the distance between the first scan line GWL and other scan lines GIL and/or GBL adjacent to the first scan line GWL may be a first distance DT1. In this case, the distance between the first scan line GWL and the second scan line GIL, and the distance between the first scan line GWL and the fourth scan line GBL may be the first distance DT1. In FIG. 12B, the distance between the first scan line GWL and the second scan line GIL, and the distance between the first scan line GWL and the fourth scan line GBL are the same as an example, but some example embodiments of the inventive concepts are not limited to this example.

The distance between the emission control line EML and other scan lines GBL and/or GCL adjacent to the emission control line EML may be a second distance DT2. In this case, the distance between the emission control line EML and the fourth scan line GBL, and the distance between the emission control line EML and the third scan line GCL may be the second distance DT2. In FIG. 12B, the distance between the emission control line EML and the fourth scan line GBL, and the distance between the emission control line EML and the third scan line GCL are the same as an example, but some example embodiments of the inventive concepts are not limited to this example.

The distance between lines may affect the capacitive load formed in each, or one or more, of the lines. For example, if the distance between lines is small, the capacitive load may increase due to interference with adjacent lines, and accordingly, the power consumption according to a change in the level of a corresponding signal may increase.

In some example embodiments of the inventive concepts, the first distance DT1 may be smaller than the second distance DT2. Therefore, as the capacitive load of each, or one or more, of the emission control line EML and/or the fourth scan line GBL, in which the level of a signal changes more frequently, is adjusted to be relatively smaller, the total power consumption of the electronic device ED (see FIG. 1) may be reduced.

In FIG. 12B, the distance between the first scan line GWL and other scan lines GIL and/or GBL adjacent to the first scan line GWL, and the distance between the emission control line EML and other scan lines GBL and/or GCL adjacent to the emission control line EML are compared as an example, but some example embodiments of the inventive concepts are not limited to this example.

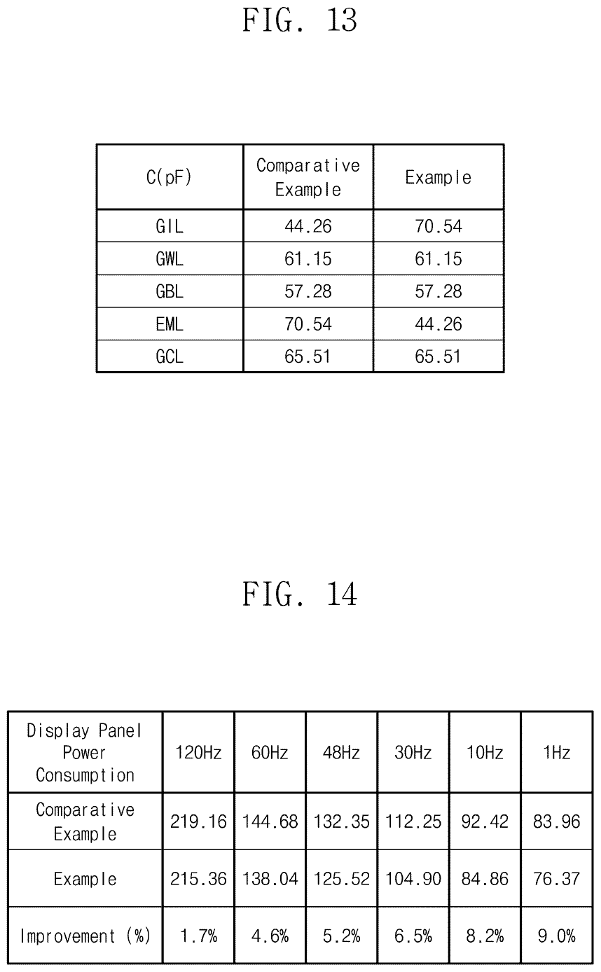

FIG. 13 is a table showing numerical values of capacitive loads of the plurality of scan lines GWL, GIL, GCL, and GBL and the emission control line EML according to some example embodiments of the inventive concepts.

Unlike in FIG. 12A and FIG. 12B, Comparative Example described in FIG. 13 shows an example in which the size of a capacitive load when the width of each of the plurality of scan lines and the emission control line or the distance between adjacent other lines are all the same, and Example described in FIG. 13 shows the size of the capacitive load in FIG. 12A or FIG. 12B as an example.

According to Comparative Example, the capacitance of a capacitive load of the emission control line may be the largest at 70.54 pF. As described above with reference to FIG. 7, unlike the first scan signal GW, the second scan signal GI, and/or the third scan signal GC, the level of the emission signal EM and/or the fourth scan signal GB may be changed in the self-period MD2 as well as in the data write period MD1. Therefore, according to Comparative Example, whenever the signal level of the emission control line is changed, the power consumption may increase by the charge-discharge of a capacitive load formed in the emission control line.

According to some example embodiments of the inventive concepts, the capacitance of the capacitive load of the emission control line EML and/or EMLa may be the smallest at 44.26 pF, and the capacitance of the capacitive load of the fourth scan line GBL may be the second smallest at 57.28 pF. Therefore, as the capacitive load of each, or one or more, of the emission control line EML and/or EMLa and/or the fourth scan line GBL, in which the level of a signal changes more frequently, is adjusted to be relatively smaller, the total power consumption of the electronic device ED (see FIG. 1) may be reduced.

In some example embodiments of the inventive concept, as the capacitive load of each, or one or more, of the first to fourth scan lines GWL, GIL, GCL, and/or GBL and the emission control line EML and/or EMLa is adjusted, the load of the second circuit CC2 corresponding to the emission signal EM and the load of the fifth circuit CC5 corresponding to the fourth scan signal GB may be adjusted to be smaller than the load of the first circuit CC1 corresponding to the first scan signal GW, the load of the third circuit CC3 corresponding to the second scan signal GI, and the load of the fourth circuit CC4 corresponding to the third scan signal GC.

Although FIG. 12A and FIG. 12B illustrate some example embodiments in which the width of lines or the distance between the lines is adjusted as an example, various other methods may be applied to adjust the capacitive load of each line.

Unlike in Comparative Example, the capacitive load of the first scan line GWL in Example may be larger than the capacitive load of the emission control line EML and/or EMLa. Therefore, the load of the first circuit CC1 including the first scan line GWL may be larger than the load of the second circuit CC2 including the emission control line EML and/or EMLa.

In some example embodiments of the inventive concepts, the capacitive load of the emission control line EML and/or EMLa may be smaller than each, or one or more, of the capacitive load of the second scan line GIL and/or the capacitive load of the third scan line GCL. Therefore, the load of the second circuit CC2 including the emission control line EML and/or EMLa may be smaller than each, or one or more, of the load of the third circuit CC3 including the second scan line GIL and/or the load of the fourth circuit CC4 including the third scan line GCL.

In some example embodiments of the inventive concepts, the capacitive load of the fourth scan line GBL may be smaller than each, or one or more, of the capacitive load of the first scan line GWL, the capacitive load of the second scan line GIL, and/or the capacitive load of the third scan line GCL. Therefore, the load of the fifth circuit CC5 including the fourth scan line GBL may be smaller than each, or one or more, of the load of the first circuit CC1 including the first scan line GWL, the load of the third circuit CC3 including the second scan line GIL and/or the load of the fourth circuit CC4 including the third scan line GCL.

FIG. 14 is a table showing the power consumption of the display panel DP (see FIG. 3) according to some example embodiments of the inventive concepts.

In FIG. 14, the power consumption of the display panel DP (see FIG. 3) for each frequency is shown in the table. Comparative Example described in FIG. 14 describes the power consumption of the display panel with respect to Comparative Example described in FIG. 13, and Example described in FIG. 14 describes the power consumption of the display panel DP (see FIG. 3) with respect to Example described in FIG. 13.

Referring to FIG. 3 and FIG. 13 together, in Comparative Example, the capacitance of the capacitive load of the emission control line may be the largest at 70.54 pF. However, according to some example embodiments of the inventive concepts, the capacitance of the capacitive load of the emission control line EML and/or EMLa may be the smallest at 44.26 pF, and the capacitance of the capacitive load of the fourth scan line GBL may be the second smallest at 57.28 pF. Therefore, as the capacitive load of each, or one or more, of the emission control line EML and/or EMLa and/or the fourth scan line GBL, in which the level of a signal changes more frequently, is adjusted to be relatively smaller, the total power consumption of the electronic device ED (see FIG. 1) may be reduced.

When the display panel DP is operated at 120 Hz, the power consumption of the display panel according to Comparative Example may be measured at 219.16 mW, and the power consumption of the display panel DP according to Example may be measured at 215.36 mW. Therefore, the power consumption may be reduced by 1.7%.

According to some example embodiments, the improvement in power consumption may be increased in low-frequency driving. For example, in a low-frequency driving mode, the number of self-periods MD2 (see FIG. 7) included in one frame may be increased. In the self-period MD2 (see FIG. 7), signals provided to the first to third scan lines GWL, GIL, and/or GCL in the self-period MD2 maintain a predetermined, or alternately given, level, and the level of signals provided to the emission control line EML and/or EMLa and/or the fourth scan line GBL may be changed. Therefore, as the capacitive load of the emission control line EML and/or EMLa and/or the fourth scan line GBL is adjusted to be relatively smaller, at 60 Hz, the power consumption may be reduced by 4.6% compared to that of Comparative Example, and at 1 Hz, the power consumption may be reduced by 9.0 compared to that of Comparative Example.

As described above, the capacitive load of an emission control line, in which the level of a signal changes relatively frequently, may be designed to be smaller than the capacitive load of a scan line, for example, a first scan line. In addition, an opening may be provided to a driving voltage line overlapping signal lines to reduce the overlapping area between the signal lines and the driving voltage line. Therefore, the capacitive load formed in the signal lines may also be further reduced. In this case, the power consumption by the charge-discharge of a capacitive load generated due to changes in the level of a signal provided to a predetermined, or alternately given, line is reduced, and therefore, the power consumption of an electronic device may be reduced.

One or more of the elements disclosed above may include or be implemented in one or more processing circuitries such as hardware including logic circuits; a hardware/software combination such as a processor executing software; or a combination thereof. For example, the processing circuitries more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

In the above, description has been made with reference to some example embodiments of the inventive concepts, but those skilled or of ordinary skill in the art may understand that various modifications and changes may be made to the inventive concepts as far as such modifications and changes do not depart from the spirit and technical scope of the inventive concepts set forth in the claims to be described later. Therefore, the technical scope of the inventive concepts are not to be limited to the contents stated in the detailed description of the specification, but should be determined by the claims.

### Description of the Reference Numerals or Symbols

ED: Electronic device DP: Display panel

DA: First region NDA: Second region

GWL: First scan line EML: Emission control line

CL1: First signal line CL2: Second signal line

CC1: First circuit CC2: Second circuit

GW-ST1: First stage EM-ST: Second stage

What is claimed is:

1. An electronic device comprising:
a base layer including a first region and a second region adjacent to the first region;
a pixel in the first region;
a plurality of scan lines in the first region, and including a first scan line electrically connected to the pixel;
an emission control line in the first region, and electrically connected to the pixel;
a scan driving circuit in the second region, and electrically connected to the plurality of scan lines;
an emission driving circuit in the second region, and electrically connected to the emission control line;
a plurality of driving voltage lines in the second region, and electrically connected to the pixel; and
a plurality of signal lines in the second region, the plurality of signal lines including
a first signal line electrically connected to the scan driving circuit, and
a second signal line electrically connected to the emission driving circuit,
wherein a load of a first circuit including the first scan line and the first signal line is larger than a load of a second circuit including the emission control line and the second signal line.

2. The electronic device of claim 1, wherein:
the plurality of scan lines further comprise a second scan line, a third scan line, and a fourth scan line; and
the plurality of signal lines further comprise a third signal line, a fourth signal line, and a fifth signal line, which are electrically connected to the scan driving circuit.

3. The electronic device of claim 1, wherein the scan driving circuit is configured to output a first scan signal to the first scan line,
wherein the emission driving circuit is configured to output an emission signal to the emission control line, and
wherein in a self-period, the scan driving circuit is configured to maintain a level of the first scan signal, and the emission driving circuit is configured to change a level of the emission signal.

4. The electronic device of claim 3, wherein the scan driving circuit is configured to output a second scan signal to the second scan line, output a third scan signal to the third scan line, and output a fourth scan signal to the fourth scan line, and
wherein in the self-period, the scan driving circuit is configured to
maintain a level of the second scan signal and a level of the third scan signal, and
change a level of the fourth scan signal.

5. The electronic device of claim 2, wherein the load of the second circuit is smaller than each of a load of a third circuit including the second scan line and the third signal line and a load of a fourth circuit including the third scan line and the fourth signal line.

6. The electronic device of claim 5, wherein a load of a fifth circuit including the fourth scan line and the fifth signal line is smaller than each of the load of the first circuit, the load of the third circuit, and the load of the fourth circuit.

7. The electronic device of claim 1, wherein a first width of the first scan line is larger than a second width of the emission control line.

8. The electronic device of claim 1, wherein a first distance between the first scan line and a plurality of other scan lines adjacent to the first scan line is smaller than a second distance between the emission control line and a plurality of other scan lines adjacent to the emission control line.

9. The electronic device of claim 1, wherein a capacitive load of the first scan line is larger than a capacitive load of the emission control line.

10. The electronic device of claim 9, wherein:
the plurality of scan lines further comprise a second scan line, a third scan line, and a fourth scan line; and
the capacitive load of the emission control line is smaller than each of a capacitive load of the second scan line and a capacitive load of the third scan line.

11. The electronic device of claim 10, wherein a capacitive load of the fourth scan line is smaller than each of the capacitive load of the first scan line, the capacitive load of the second scan line, and the capacitive load of the third scan line.

12. The electronic device of claim 1, wherein the plurality of driving voltage lines comprise a first driving voltage line to which a first driving voltage is provided and a second driving voltage line to which a second driving voltage is provided,
wherein:
the first driving voltage line includes a first overlapping portion overlapping the plurality of signal lines on a plane; and
the second driving voltage line includes a second overlapping portion overlapping the plurality of signal lines on the plane.

13. The electronic device of claim 12, wherein the first overlapping portion includes a first opening.

14. The electronic device of claim 13, wherein the first opening includes a plurality of first openings.

15. The electronic device of claim 12, wherein the first overlapping portion includes a first opening, and the second overlapping portion includes a second opening.

16. The electronic device of claim 15, wherein the first opening includes a plurality of first openings and the second opening includes a plurality of second openings.

17. An electronic device comprising:
a display panel including a display region and a non-display region adjacent to the display region, wherein the display panel includes:
a pixel in the display region, and including a pixel circuit and an emission element;
a first scan line electrically connected to the pixel circuit; and
an emission control line electrically connected to the pixel circuit,
wherein a capacitive load of the first scan line is larger than a capacitive load of the emission control line.

18. The electronic device of claim 17, further comprising processing circuitry configured to:
operate the pixel circuit based on a data write period and a self-period;
change a level of a first scan signal provided to the first scan line in the data write period;
maintain the level of the first scan signal provided to the first scan line in the self-period; and
change a level of an emission signal provided to the emission control line in the data write period and the self-period.

19. The electronic device of claim 18, wherein the display panel further comprises a second scan line, a third scan line, and a fourth scan line,
wherein the capacitive load of the emission control line is smaller than each of a capacitive load of the second scan line, and a capacitive load of the third scan line,
wherein a capacitive load of the fourth scan line is smaller than each of the capacitive load of the first scan line, the capacitive load of the second scan line, and the capacitive load of the third scan line, and
wherein the processing circuitry is configured to
maintain a level of each of signals provided to the second scan line and the third scan line in the self-period, and
change a level of a signal provided to the fourth scan line in the self-period.

20. The electronic device of claim 17, wherein the display panel further comprises:
a plurality of signal lines in the non-display region; and
a driving voltage line in the non-display region, the driving voltage line configured to transfer a driving voltage to the pixel, the driving voltage line including at least one opening overlapping the plurality of signal lines on a plane.
